(19) United States
(12) Patent Application Publication
(10) Pub. No.: US 2023/0167326 A1
(43) Pub. Date: Jun. 1, 2023

(54) Methods for Forming Perovskite Material Layers

(71) Applicant: CubicPV Inc., Dallas, TX (US)

(72) Inventors: Michael D. Irwin, Heath, TX (US); Minh Tu Nguyen, Dallas, TX (US); Vivek V. Dhas, Dallas, TX (US); Erin Senehira, Dallas, TX (US); Marissa Mitchell, Forney, TX (US)

(21) Appl. No.: 18/070,267

(22) Filed: Nov. 28, 2022

Related U.S. Application Data
(60) Provisional application No. 63/283,525, filed on Nov. 28, 2021.

(51) Int. Cl. C09D 11/52; C01G 21/16; C09D 11/033

(52) U.S. Cl. CPC C09D 11/52; C01G 21/16; C09D 11/033; H01L 51/4213

(57) ABSTRACT

A method including depositing a lead halide precursor ink onto a substrate; drying the lead halide precursor ink to form a first thin film; annealing the first thin film; and forming a perovskite material layer, wherein forming the perovskite material layer includes: depositing a benzylammonium halide precursor ink onto the first thin film; drying the benzylammonium halide precursor ink; depositing a formamidinium halide precursor ink onto the benzylammonium halide precursor ink; drying the formamidinium halide precursor ink to form a second thin film; and annealing the second thin film.

### CROSS-REFERENCE TO RELATED APPLICATIONS

This application claims priority to U.S. Provisional Patent Application No. 63/283,525 filed Nov. 28, 2021 and entitled “METHOD FOR FORMING PEROVSKITE MATERIAL LAYERS”, the contents of which are incorporated by reference herein in its entirety.

### BACKGROUND

Use of photovoltaics (PVs) to generate electrical power from solar energy or radiation may provide many benefits, including, for example, a power source, low or zero emissions, power production independent of the power grid, durable physical structures (no moving parts), stable and reliable systems, modular construction, relatively quick installation, safe manufacture and use, and good public opinion and acceptance of use. Perovskite photovoltaics, as emerging high-efficiency and low-cost photovoltaic technology, face obstacles like lead leakage.

PVs may incorporate layers of perovskite materials as photoactive layers that generate electric power when exposed to light. Some perovskite photovoltaics include lead and other metal ions that may be susceptible to leakage. Therefore, improvements to lead and metal ion sequestration techniques and materials are desirable.

### SUMMARY

According to certain embodiments, a method includes: forming a lead halide precursor thin film, wherein forming the lead halide precursor thin film includes: depositing a lead halide precursor ink onto a substrate; drying the lead halide precursor ink to form a first thin film; and annealing the first thin film. In some embodiments, the method further includes forming a perovskite material layer, wherein forming the perovskite material layer includes: depositing a benzylammonium halide precursor ink onto the first thin film; drying the benzylammonium halide precursor ink; depositing a formamidinium halide precursor ink onto the benzylammonium halide precursor ink; drying the formamidinium halide precursor ink to form a second thin film; and annealing the second thin film.

### BRIEF DESCRIPTION OF THE DRAWINGS

FIG. 1 is a schematic diagram illustrating components of a photovoltaic device according to some embodiments of the present disclosure.

FIG. 2 is a stylized diagram showing components of an example PV device according to some embodiments of the present disclosure.

FIG. 3 is a stylized diagram showing components of an example PV device according to some embodiments of the present disclosure.

FIG. 4 is a stylized diagram showing components of an example PV device according to some embodiments of the present disclosure.

FIG. 5 illustrates x-ray diffraction patterns of perovskites materials according to some embodiments of the present disclosure.

FIG. 6 is a stylized illustration of a blade coating setup for manufacturing perovskite material layer.

FIG. 7 is a stylized illustration of a blade coating setup for forming a perovskite material layer.

FIG. 8 is a stylized illustration of a slot die coating setup for manufacturing a perovskite material layer.

FIG. 9 is a schematic diagram illustrating components of a photovoltaic device according to some embodiments of the present disclosure.

FIG. 10 is a stylized illustration of a slot die coating setup for manufacturing a perovskite material layer.

### DETAILED DESCRIPTION OF PREFERRED EMBODIMENTS

The features and advantages of the present disclosure will be readily apparent to those skilled in the art. While numerous changes may be made by those skilled in the art, such changes are within the spirit of the invention.

The present disclosure relates generally to compositions of matter, apparatus and methods of use of materials in photovoltaic cells in creating electrical energy from solar radiation. Some or all of materials in accordance with some embodiments of the present disclosure may also advantageously be used in any organic or other electronic device, with some examples including, but not limited to: batteries, field-effect transistors (FETs), light-emitting diodes (LEDs), non-linear optical devices, transistors, ionizing radiation detectors, memristors, capacitors, rectifiers, and/or rectifying antennas.

In some embodiments, the present disclosure may provide PV and other similar devices (e.g., batteries, hybrid PV batteries, multi junction PVs, FETs, LEDs, x-ray detectors, gamma ray detectors, photodiodes, CCDs, etc.). Such devices may in some embodiments include improved active material, interfacial layers (IFLs), and/or one or more perovskite materials. A perovskite material may be incorporated into various of one or more aspects of a PV or other device. Perovskite materials according to various embodiments are discussed in greater detail below.

Photovoltaic Cells and Other Electronic Devices

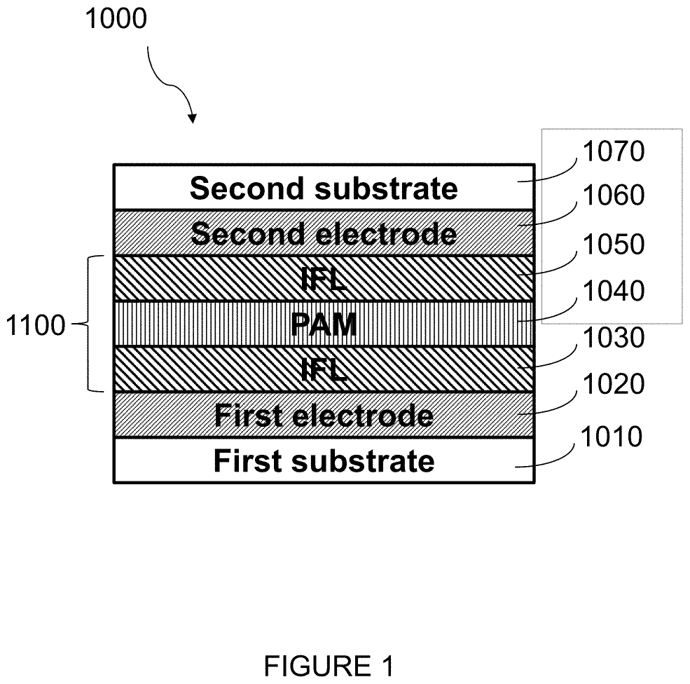

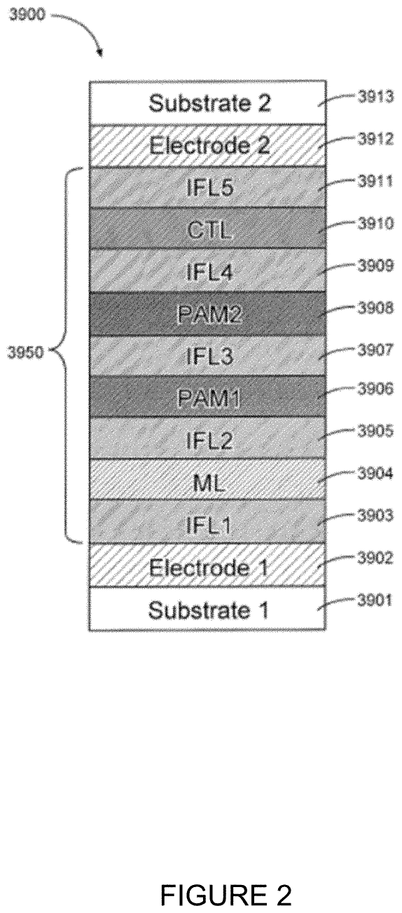

Some PV embodiments may be described by reference to the illustrative depictions of a perovskite material device as shown in FIG. 1. An example PV architecture according to some embodiments may be substantially of the form substrate-anode-IFL-active layer-IFL-cathode. The active layer of some embodiments may be photoactive, and/or it may include photoactive material. Other layers and materials may be utilized in the cell as is known in the art. Furthermore, it should be noted that the use of the term “active layer” is in no way meant to restrict or otherwise define, explicitly or implicitly, the properties of any other layer—for instance, in some embodiments, either or both IFLs may also be active insofar as they may be semiconducting. In particular, referring to FIG. 1, a stylized generic PV cell 1000 is depicted, illustrating the highly interfacial nature of some layers within the PV. The PV 1000 represents a generic architecture applicable to several PV devices, such as perovskite material PV embodiments. The PV cell 1000 includes a transparent substrate layers 1010 and 1070, which may be glass (or a material similarly transparent to solar radiation) which allows solar radiation to transmit through the layer. The transparent layer of some embodiments may also be referred to as a superstrate or substrate, and it may comprise any one or more of a variety of rigid or flexible materials such as: glass, polyethylene, polypropylene, polycarbonate, polyimide, PMMA, PET, PEN, Kapton, or quartz. In general, the term substrate is used to refer to material upon which the device is deposited during manufacturing. The photoactive (PAM) layer 1040 may be composed of electron donor or p-type material, and/or an electron acceptor or n-type material, and/or an ambipolar semiconductor, which exhibits both p- and n-type material characteristics, and/or an intrinsic semiconductor which exhibits neither n-type or p-type characteristics. Photoactive layer 1040 may be a perovskite material as described herein, in some embodiments. The active layer or, as depicted in FIG. 1, the PAM layer 1040, is sandwiched between two electrically conductive electrode layers 1020 and 1060. In FIG. 1, the electrode layer 1020 may be a transparent conductor such as a tin-doped indium oxide (ITO material) or other material as described herein. In some embodiments, the second electrode 1060 may be transparent. The second electrode layer 1060 may be an aluminum material or other metal, or other conductive materials such as carbon. Other materials may be used as is known in the art. The cell 1100 also includes an interfacial layer (IFL) 1030, shown in the example of FIG. 1. The IFL may assist in charge separation. In other embodiments, the IFL 1030 may comprise a multi-layer IFL. For example, a perovskite material device may contain zero, one, two, three, four, five, or more interfacial layers (such as the example device of FIG. 2, which contains five interfacial layers 3903, 3905, 3907, 3909, and 3911). There also may be an IFL 1050 adjacent to the second electrode 1060. In some embodiments, the IFL 1050 adjacent to the second electrode 1060 may also or instead comprise a multi-layer IFL. An IFL according to some embodiments may be semiconducting in character and may be either intrinsic, ambipolar, p-type, or n-type, or it may be dielectric in character. In some embodiments, the IFL on the cathode side of the device (e.g., IFL 1050 as shown in FIG. 1) may be p-type, and the IFL on the anode side of the device (e.g., IFL 1030 as shown in FIG. 1) may be n-type. In other embodiments, however, the cathode-side IFL may be n-type and the anode-side IFL may be p-type. The cell 1100 may be attached to electrical leads by electrodes 1060 and 1020 and a discharge unit, such as a battery, motor, capacitor, electric grid, or any other electrical load.

Various embodiments of the present disclosure provide improved materials and/or designs in various aspects of solar cell and other devices, including among other things, active materials (including hole-transport and/or electron-transport layers), interfacial layers, and overall device design.

According to various embodiments, devices may optionally include an interfacial layer between any two other layers and/or materials, although devices need not contain any interfacial layers. For example, a perovskite material device may contain zero, one, two, three, four, five, or more interfacial layers (such as the example device of FIG. 2, which contains five interfacial layers 3903, 3905, 3907, 3909, and 3911). An interfacial layer may include any suitable material for enhancing charge transport and/or collection between two layers or materials; it may also help prevent or reduce the likelihood of charge recombination once a charge has been transported away from one of the materials adjacent to the interfacial layer. An interfacial layer may additionally physically and electrically homogenize its substrates to create variations in substrate roughness, dielectric constant, adhesion, creation or quenching of defects (e.g., charge traps, surface states). Suitable interfacial materials may include any one or more of: Ag; Al; Au; B; Bi; Ca; Cd; Ce; Co; Cu; Fe; Ga; Ge; H; In; Mg; Mn; Mo; Nb; Ni; Pt; Sb; Sc; Si; Sn; Ta; Ti; V; W; Y; Zn; Zr; carbides of any of the foregoing metals (e.g., SiC, Fe₃C, WC, VC, MoC, NbC); silicides of any of the foregoing metals (e.g., Mg₂Si, SrSi₂, Sn₂Si); oxides of any of the foregoing metals (e.g., alumina, silica, titania, Sn₀₂, ZnO, NiO, ZrO₂, HfO₂), include transparent conducting oxides (“TCOs”) such as indium tin oxide, aluminum doped zinc oxide (AZO), cadmium oxide (CdO), and fluorine doped tin oxide (FTO); sulfides of any of the foregoing metals (e.g., CdS, MoS₂, SnS₂); nitrides of any of the foregoing metals (e.g., GaN, Mg₃N₂, TiN, BN, Si₃N₄); selenides of any of the foregoing metals (e.g., CdSe, FeS₂, ZnSe); tellurides of any of the foregoing metals (e.g., CdTe, TiTe₂, ZnTe); phosphides of any of the foregoing metals (e.g., InP, GaP, GaInP); arsenides of any of the foregoing metals (e.g., CoAs₃, GaAs, InGaAs, NiAs); antimonides of any of the foregoing metals (e.g., AlSb, GaSb, InSb); halides of any of the foregoing metals (e.g., CuCl, CuI, BiI₃); pseudohalides of any of the foregoing metals (e.g., CuSCN, AuCN, Fe(SCN)₂); carbonates of any of the foregoing metals (e.g., CaCO₃, Ce₂(CO₃)₃); functionalized or non-functionalized alkyl silyl groups; graphite; graphene; fullerenes; carbon nanotubes; any mesoporous material and/or interfacial material discussed elsewhere herein; and combinations thereof (including, in some embodiments, bilayers, trilayers, or multi-layers of combined materials). In some embodiments, an interfacial layer may include perovskite material. Further, interfacial layers may comprise doped embodiments of any interfacial material mentioned herein (e.g., Y-doped ZnO, N-doped single-wall carbon nanotubes). Interfacial layers may also comprise a compound having three of the above materials (e.g., CuTiO₃, Zn₂SnO₄) or a compound having four of the above materials (e.g., CoNiZnO). The materials listed above may be present in a planar, mesoporous or otherwise nano-structured form (e.g. rods, spheres, flowers, pyramids), or aerogel structure. U.S. Pat. No. 11,171,290, incorporated herein by reference in its entirety, describes additional types of interfacial layers and suitable materials for IFLs of the present disclosure.

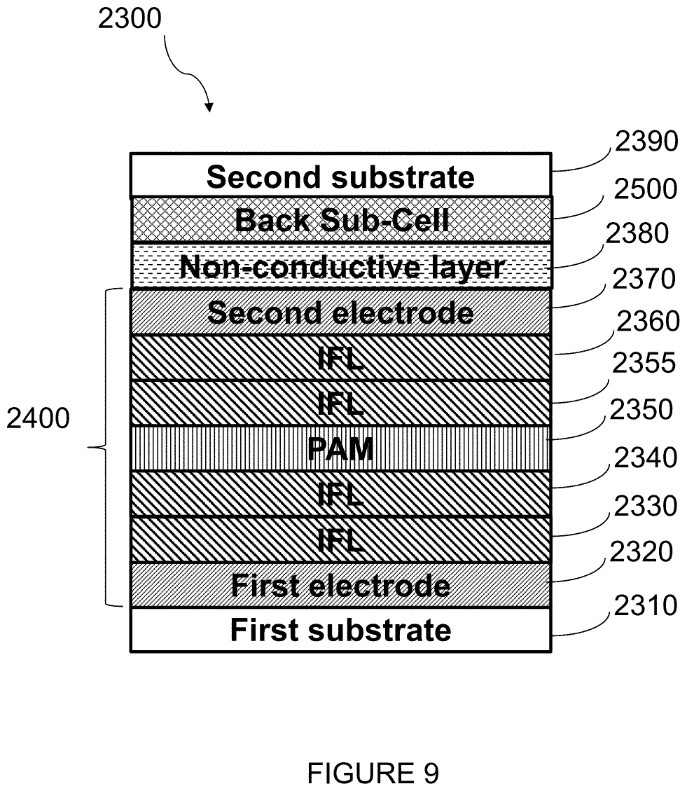

Additionally, some perovskite material PV cells may include so called “tandem” PV devices having more than one perovskite photoactive layer. An example of a tandem PV device is shown in FIG. 2, which includes two photoactive materials 2040 and 2060. In some embodiments, both photoactive materials 2040 and 2060 of FIG. 2 may be perovskite materials. FIG. 2 depicts a two-terminal tandem PV device 2000, i.e., the two photoactive materials are integrated together into a single monolithic PV cell. In such tandem PV cells an interfacial layer between the two photoactive layers, such as IFL 2050 and 2055 of FIG. 2 may comprise a multi-layer, or composite, IFL. In some embodiments, the layers sandwiched between the two photoactive layers of a tandem PV device may include an electrode layer. In some embodiments, a tandem PV device may be a four-terminal device, such as the device shown in FIG. 9. Four-terminal tandem PV devices may include two sub-cells that are electrically independent from each other but optically coupled.

A two-terminal tandem PV device may include the following layers, listed in order from either top to bottom or bottom to top: a first substrate, a first electrode, a first interfacial layer, a first perovskite material, a second interfacial layer, a second electrode, a third interfacial layer, a second perovskite material, a fourth interfacial layer, and a third electrode. In some embodiments, the first and third interfacial layers may be hole transporting interfacial layers and the second and fourth interfacial layers may be electron transporting interfacial layers. In other embodiments, the first and third interfacial layers may be electron transporting interfacial layers and the second and fourth interfacial layers may be hole transporting interfacial layers. In yet other embodiments, the first and fourth interfacial layers may be hole transporting interfacial layers and the second and third interfacial layers may be electron transporting interfacial layers. In other embodiments, the first and fourth interfacial layers may be electron transporting interfacial layers and the second and third interfacial layers may be hole transporting interfacial layers. In tandem PV devices the first and second perovskite materials may have different band gaps. In some embodiments, the first perovskite material may be formamidinium lead bromide (FAPbBr₃) and the second perovskite material may be formamidinium lead iodide (FAPbI₃). In other embodiments, the first perovskite material may be methylammonium lead bromide (MAPbBr₃) and the second perovskite material may be formamidinium lead iodide (FaPbI₃). In other embodiments, the first perovskite material may be methylammonium lead bromide (MAPbBr₃) and the second perovskite material may be methylammonium lead iodide (MAPbI₃).

Perovskite Material

A perovskite material may be incorporated into one or more aspects of a PV or other device. A perovskite material according to some embodiments may be of the general formula C_{w}M_{y}X_{z}, where: C comprises one or more cations (e.g., an amine, ammonium, phosphonium a Group 1 metal, a Group 2 metal, and/or other cations or cation-like compounds); M comprises one or more metals (examples including Be, Mg, Ca, Sr, Ba, Fe, Cd, Co, Ni, Cu, Ag, Au, Hg, Sn, Ge, Ga, Pb, In, Tl, Sb, Bi, Ti, Zn, Cd, Hg, and Zr); X comprises one or more anions; and w, y, and z represent real numbers between 1 and 20. In some embodiments, C may include one or more organic cations. In some embodiments, each organic cation C may be larger than each metal M, and each anion X may be capable of bonding with both a cation C and a metal M.

In certain embodiments, C may include an ammonium, an organic cation of the general formula [NR₄]⁺ where the R groups may be the same or different groups. Suitable R groups include, but are not limited to: hydrogen, methyl, ethyl, propyl, butyl, pentyl group or isomer thereof; any alkane, alkene, or alkyne CxHy, where x=1-20, y=1-42, cyclic, branched or straight-chain; alkyl halides, CxHyXz, x=1-20, y=0-42, z=1-42, X=F, Cl, Br, or I; any aromatic group (e.g., phenyl, alkylphenl, alkoxyphenyl, pyridine, naphthalene); cyclic complexes where at least one nitrogen is contained within the ring (e.g., pyridine, pyrrole, pyrrolidine, piperidine, tetrahydroquinoline); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (e.g., acetic acid, propanoic acid); and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCxHy, where x=0-20, y=1-42.

In certain embodiments, C may include a formamidinium, an organic cation of the general formula [R₂NCRNR₂]⁺ where the R groups may be the same or different groups. Suitable R groups include, but are not limited to: hydrogen, methyl, ethyl, propyl, butyl, pentyl group or isomer thereof; any alkane, alkene, or alkyne CxHy, where x=1-20, y=1-42, cyclic, branched or straight-chain; alkyl halides, CxHyXz, x=1-20, y=0-42, z=1-42, X=F, Cl, Br, or I; any aromatic group (e.g., phenyl, alkylphenl, alkoxyphenyl, pyridine, naphthalene); cyclic complexes where at least one nitrogen is contained within the ring (e.g., imidazole, benzimidazole, pyrimidine, (azolidinylidenemethyl)pyrrolidine, triazole); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCxHy, where x=0-20, y=1-42.

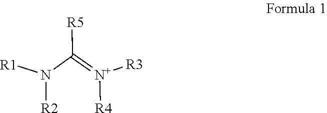

Formula 1 illustrates the structure of a formamidinium cation having the general formula of [R₂NCRNR₂]⁺ as described above. Formula 2 illustrates examples structures of several formamidinium cations that may serve as a cation “C” in a perovskite material.

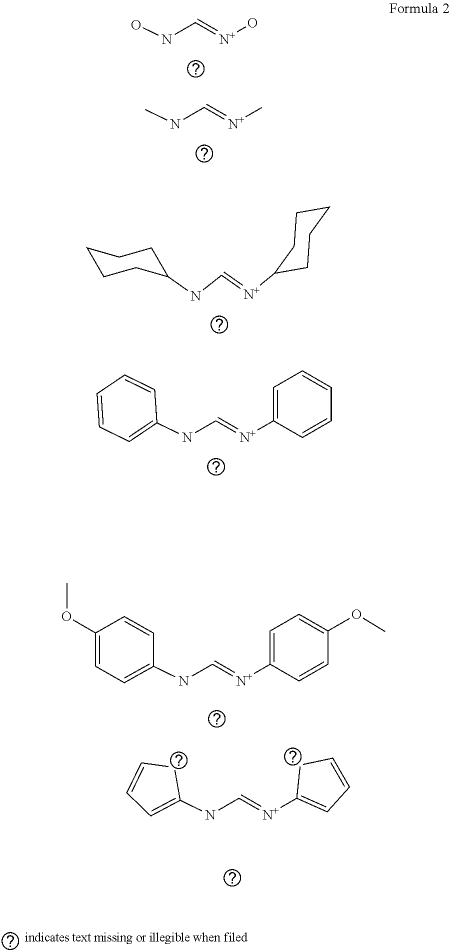

In certain embodiments, C may include a guanidinium, an organic cation of the general formula [(R₂N)₂C═NR₂]⁺ where the R groups may be the same or different groups. Suitable R groups include, but are not limited to: hydrogen, methyl, ethyl, propyl, butyl, pentyl group or isomer thereof; any alkane, alkene, or alkyne CxHy, where x=1-20, y=1-42, cyclic, branched or straight-chain; alkyl halides, CxHyXz, x=1-20, y=0-42, z=1-42, X=F, Cl, Br, or I; any aromatic group (e.g., phenyl, alkylphenl, alkoxyphenyl, pyridine, naphthalene); cyclic complexes where at least one nitrogen is contained within the ring (e.g., octahydropyrimido[1,2-a]pyrimidine, pyrimido[1,2-a]pyrimidine, hexahydroimidazo[1,2-a]imidazole, hexahydropyrimidin-2-imine); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCxHy, where x=0-20, y=1-42.

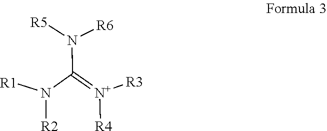

Formula 3 illustrates the structure of a guanidinium cation having the general formula of [(R₂N)₂C═NR₂]⁺ as described above. Formula 4 illustrates examples of structures of several guanidinium cations that may serve as a cation “C” in a perovskite material.

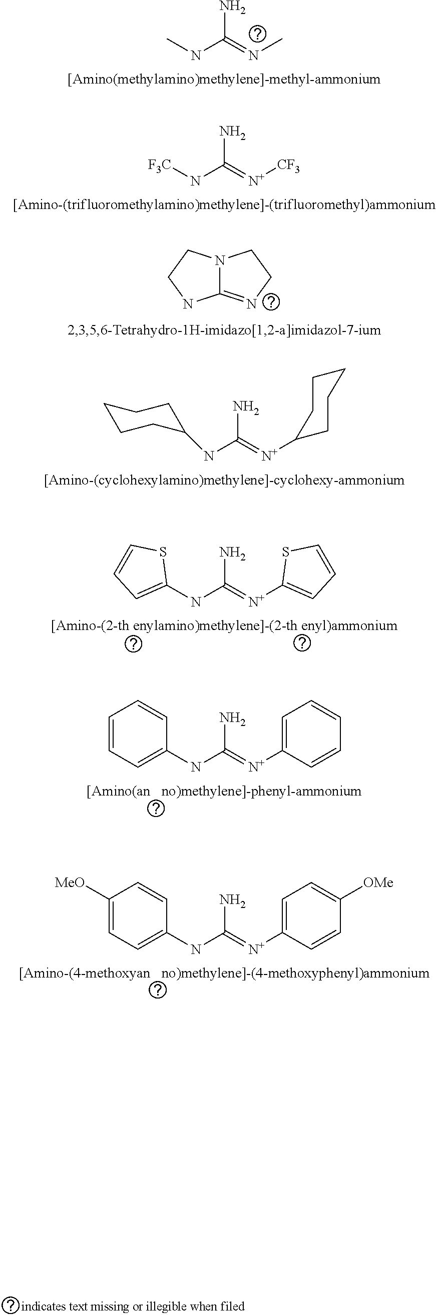

In certain embodiments, C may include an ethene tetramine cation, an organic cation of the general formula [(R₂N)₂C═C(NR₂)₂]⁺ where the R groups may be the same or different groups. Suitable R groups include, but are not limited to: hydrogen, methyl, ethyl, propyl, butyl, pentyl group or isomer thereof; any alkane, alkene, or alkyne CxHy, where x=1-20, y=1-42, cyclic, branched or straight-chain; alkyl halides, CxHyXz, x=1-20, y=0-42, z=1-42, X=F, Cl, Br, or I; any aromatic group (e.g., phenyl, alkylphenl, alkoxyphenyl, pyridine, naphthalene); cyclic complexes where at least one nitrogen is contained within the ring (e.g., 2-hexahydropyrimidin-2-ylidenehexahydropyrimidine, octahydropyrazino[2,3-b]pyrazine, pyrazino[2,3-b]pyrazine, quinoxalino[2,3-b]quinoxaline); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCxHy, where x=0-20, y=1-42.

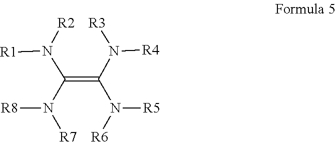

Formula 5 illustrates the structure of an ethene tetramine cation having the general formula of [(R₂N)₂C═C(NR₂)₂]⁺ as described above. Formula 6 illustrates examples of structures of several ethene tetramine ions that may serve as a cation “C” in a perovskite material.

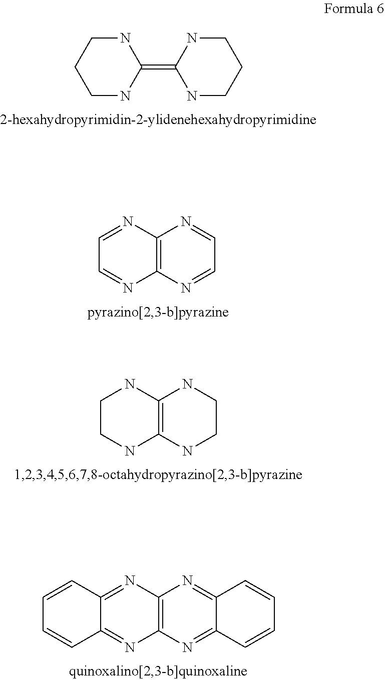

In certain embodiments, C may include an imidazolium cation, an aromatic, cyclic organic cation of the general formula [CRNRCRNRCR]⁺ where the R groups may be the same or different groups. Suitable R groups may include, but are not limited to: hydrogen, methyl, ethyl, propyl, butyl, pentyl group or isomer thereof; any alkane, alkene, or alkyne CxHy, where x=1-20, y=1-42, cyclic, branched or straight-chain; alkyl halides, CxHyXz, x=1-20, y=0-42, z=1-42, X=F, Cl, Br, or I; any aromatic group (e.g., phenyl, alkylphenl, alkoxyphenyl, pyridine, naphthalene); cyclic complexes where at least one nitrogen is contained within the ring (e.g., 2-hexahydropyrimidin-2-ylidenehexahydropyrimidine, octahydropyrazino[2,3-b]pyrazine, pyrazino[2,3-b]pyrazine, quinoxalino[2,3-b]quinoxaline); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCxHy, where x=0-20, y=1-42.

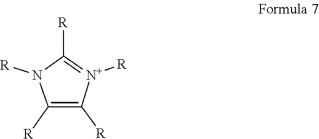

In some embodiments, X may include one or more halides. In certain embodiments, X may instead or in addition include a Group 16 anion. In certain embodiments, the Group 16 anion may be oxide, sulfide, selenide, or telluride. In certain embodiments, X may instead or in addition include one or more a pseudohalides (e.g., cyanide, cyanate, isocyanate, fulminate, thiocyanate, isothiocyanate, azide, tetracarbonylcobaltate, carbamoyldicyanomethanide, dicyanonitrosomethanide, dicyanamide, and tricyanomethanide). By way of explanation, and without implying any limitations, exemplary embodiments of perovskite material having a formula C_{w}M_{y}X_{z}, are discussed below.

In one embodiment, a perovskite material may comprise the empirical formula CMX₃ where: M comprises one of the aforementioned metals, C comprises one or more of the aforementioned cations, a Group 1 metal, a Group 2 metal, and/or other cations or cation-like compounds.

In another embodiment, a perovskite material may comprise the empirical formula C′M₂X₆ where: C′ comprises a cation with a 2+ charge including one or more of the aforementioned cations, diammonium butane, a Group 1 metal, a Group 2 metal, and/or other cations or cation-like compounds.

In another embodiment, a perovskite material may comprise the empirical formula C′MX₄ where: C′ comprises a cation with a 2+ charge including one or more of the aforementioned cations, diammonium butane, a Group 1 metal, a Group 2 metal, and/or other cations or cation-like compounds In such an embodiment, the perovskite material may have a 2D structure.

In one embodiment, a perovskite material may comprise the empirical formula C₃M₂X₉ where: C comprises one or more of the aforementioned cations, a Group 1 metal, a Group 2 metal, and/or other cations or cation-like compounds.

In one embodiment, a perovskite material may comprise the empirical formula CM₂X₇ where: C comprises one or more of the aforementioned cations, a Group 1 metal, a Group 2 metal, and/or other cations or cation-like compounds.

In one embodiment, a perovskite material may comprise the empirical formula C₂MX₄ where: C comprises one or more of the aforementioned cations, a Group 1 metal, a Group 2 metal, and/or other cations or cation-like compounds. Perovskite materials may also comprise mixed ion formulations where C, M, or X comprise two or more species. In some embodiments, the perovskite material may comprise two or more anions or three or more anions. In some embodiments, the perovskite material may comprise two more cations or three or more cations. In certain embodiments, the perovskite material may comprise two or more metals or three or more metals.

In one example, a perovskite material in the active layer may have the formulation CMX_{3-y}X′_{y} (0≥y≥3), where: C comprises one or more cations (e.g., an amine, ammonium, a Group 1 metal, a Group 2 metal, formamidinium, guanidinium, ethene tetramine, phosphonium, imidazolium, and/or other cations or cation-like compounds); M comprises one or more metals (e.g., Be, Mg, Ca, Sr, Ba, Fe, Cd, Co, Ni, Cu, Ag, Au, Hg, Sn, Ge, Ga, Pb, In, Tl, Sb, Bi, Ti, Zn, Cd, Hg, and Zr); and X and X′ comprise one or more anions. In one embodiment, the perovskite material may comprise CPbI_{3-y}Cl_{y}. In another example, a perovskite material in the active layer may have the formulation C₁₋ₓC′ₓMX₃ (0≥x≥1), where C and C′ comprise one or more cations as discussed above. In another example, a perovskite material in the active layer may have the formulation CM_{1-z}M′_{z}X₃ (0≥z≥1), where M and M′ comprise one or more metals as discussed above. In one example, a perovskite material in the active layer may have the formulation C₁₋ₓC′ₓM_{1-z}M′_{z}X_{3-y}X′_{y} (0≥x≥1; 0≥y≥3; 0≥z≥1), where: C and C′ comprise one or more cations as discussed above; M and M′ comprise one or more metals as discussed above; and X and X′ comprise one or more anions as discussed above.

By way of explanation, and without implying any limitations, exemplary embodiments of perovskite material may be Cs_{0.1}FA_{0.9}Pb(I_{0.9}Cl_{0.1})₃; Rb_{0.1}FA_{0.9}Pb(I_{0.9}Cl_{0.1})₃Cs_{0.1}FA_{0.9}PbI₃; FAPb_{0.5}Sn_{0.5}I₃; FA_{0.83}Cs_{0.17}Pb(I_{0.6}Br_{0.4})₃; FA_{0.83}Cs_{0.12}Rb_{0.05}Pb(I_{0.6}Br_{0.4})₃ and FA_{0.85}MA_{0.15}Pb(I_{0.85}Br_{0.15})₃.

Composite Perovskite Material Device Design

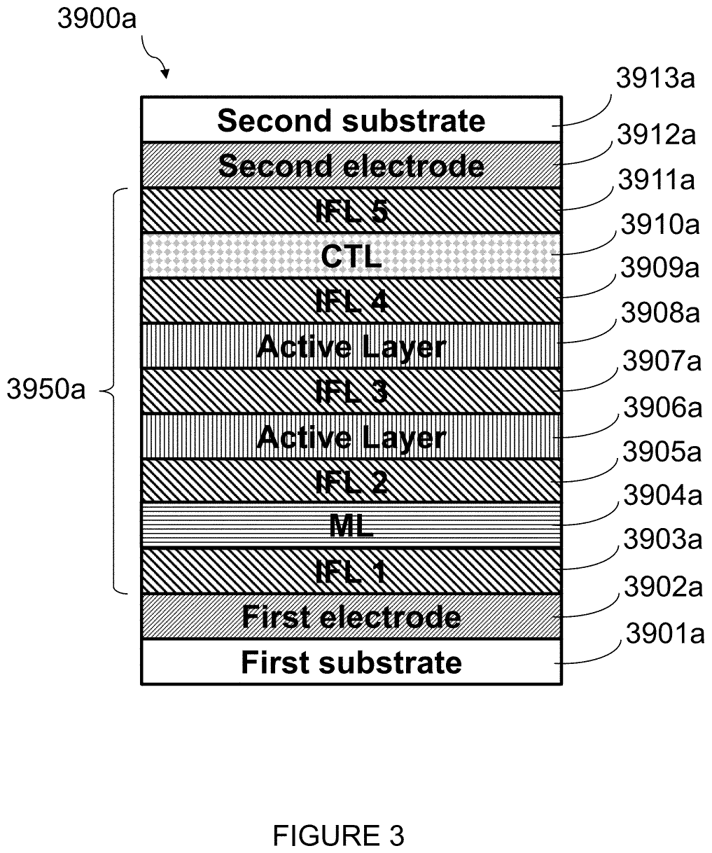

In some embodiments, the present disclosure may provide composite design of PV and other similar devices (e.g., batteries, hybrid PV batteries, FETs, LEDs, nonlinear optics (NLOs), waveguides, etc.) including one or more perovskite materials. For example, one or more perovskite materials may serve as either or both of first and second active material of some embodiments (e.g., active materials 3906a and 3908a of FIG. 3). In more general terms, some embodiments of the present disclosure provide PV or other devices having an active layer comprising one or more perovskite materials. In such embodiments, perovskite material (that is, material including any one or more perovskite materials(s)) may be employed in active layers of various architectures. Furthermore, perovskite material may serve the function(s) of any one or more components of an active layer, discussed in greater detail below. In some embodiments, the same perovskite materials may serve multiple such functions, although in other embodiments, a plurality of perovskite materials may be included in a device, each perovskite material serving one or more such functions. In certain embodiments, whatever role a perovskite material may serve, it may be prepared and/or present in a device in various states. For example, it may be substantially solid in some embodiments. A solution or suspension may be coated or otherwise deposited within a device (e.g., on another component of the device such as a mesoporous, interfacial, charge transport, photoactive, or other layer, and/or on an electrode). Perovskite materials in some embodiments may be formed in situ on a surface of another component of a device (e.g., by vapor deposition as a thin-film solid). Any other suitable means of forming a layer comprising perovskite material may be employed.

In general, a perovskite material device may include a first electrode, a second electrode, and an active layer comprising a perovskite material, the active layer disposed at least partially between the first and second electrodes. In some embodiments, the first electrode may be one of an anode and a cathode, and the second electrode may be the other of an anode and cathode. An active layer according to certain embodiments may include any one or more active layer components, including any one or more of: charge transport material; liquid electrolyte; mesoporous material; photoactive material (e.g., a dye, silicon, cadmium telluride, cadmium sulfide, cadmium selenide, copper indium gallium selenide, gallium arsenide, germanium indium phosphide, semiconducting polymers, other photoactive materials)); and interfacial material. Any one or more of these active layer components may include one or more perovskite materials. In some embodiments, some or all of the active layer components may be in whole or in part arranged in sub-layers. For example, the active layer may comprise any one or more of: an interfacial layer including interfacial material; a mesoporous layer including mesoporous material; and a charge transport layer including charge transport material. Further, an interfacial layer may be included between any two or more other layers of an active layer according to some embodiments and/or between an active layer component and an electrode. Reference to layers herein may include either a final arrangement (e.g., substantially discrete portions of each material separately definable within the device), and/or reference to a layer may mean arrangement during construction of a device, notwithstanding the possibility of subsequent intermixing of material(s) in each layer. Layers may in some embodiments be discrete and comprise substantially contiguous material (e.g., layers may be as stylistically illustrated in FIG. 1).

In some embodiments, a perovskite material device may be a field effect transistor (FET). An FET perovskite material device may include a source electrode, drain electrode, gate electrode, dielectric layer, and a semiconductor layer. In some embodiments the semiconductor layer of an FET perovskite material device may be a perovskite material.

A perovskite material device according to some embodiments may optionally include one or more substrates. In some embodiments, either or both of the first and second electrode may be coated or otherwise disposed upon a substrate, such that the electrode is disposed substantially between a substrate and the active layer. The materials of composition of devices (e.g., substrate, electrode, active layer and/or active layer components) may in whole or in part be either rigid or flexible in various embodiments. In some embodiments, an electrode may act as a substrate, thereby negating the need for a separate substrate.

Furthermore, a perovskite material device according to certain embodiments may optionally include an anti-reflective layer or anti-reflective coating (ARC).

Description of some of the various materials that may be included in a perovskite material device will be made in part with reference to FIG. 2. FIG. 2 is a stylized diagram of a tandem two-terminal perovskite material device 3900 according to some embodiments. Although various components of the device in FIG. 2 and other figures of the present disclosure depicting perovskite devices (e.g., FIGS. 1, 3-4, and 9) are illustrated as discrete layers comprising contiguous material, it should be understood that such figures are a stylized diagrams; thus, embodiments in accordance with it may include such discrete layers, and/or substantially intermixed, non-contiguous layers, consistent with the usage of “layers” previously discussed herein. The device 3900 includes first and second substrates 3901 and 3913. A first electrode 3902 is disposed upon an inner surface of the first substrate 3901, and a second electrode 3912 is disposed on an inner surface of the second substrate 3913. An active layer 3950 is sandwiched between the two electrodes 3902 and 3912. The active layer 3950 includes a mesoporous layer 3904; first and second photoactive materials 3906 and 3908; a charge transport layer (CTL) 3910, and several interfacial layers. FIG. 2 furthermore illustrates an example device 3900 according to embodiments wherein sub-layers of the active layer 3950 are separated by the interfacial layers, and further wherein interfacial layers are disposed upon each electrode 3902 and 3912. In particular, second, third, and fourth interfacial layers 3905, 3907, and 3909 are respectively disposed between each of the mesoporous layer 3904, first photoactive material 3906, second photoactive material 3908, and charge transport layer 3910. First and fifth interfacial layers 3903 and 3911 are respectively disposed between (i) the first electrode 3902 and mesoporous layer 3904; and (ii) the charge transport layer 3910 and second electrode 3912. Thus, the architecture of the example device depicted in FIG. 2 may be characterized as: substrate-electrode-active layer-electrode-substrate. The architecture of the active layer 3950 may be characterized as: interfacial layer-mesoporous layer-interfacial layer-photoactive material-interfacial layer-photoactive material-interfacial layer-charge transport layer-interfacial layer. In some embodiments, interfacial layers need not be present; or, one or more interfacial layers may be included only between certain, but not all, components of an active layer and/or components of a device.

A substrate, such as either or both of first and second substrates 3901 and 3913, may be flexible or rigid. If two substrates are included, at least one should be transparent or translucent to electromagnetic (EM) radiation (such as, e.g., UV, visible, or IR radiation). If one substrate is included, it may be similarly transparent or translucent, although it need not be, so long as a portion of the device permits EM radiation to contact the active layer 3950. Suitable substrate materials include any one or more of: glass; sapphire; magnesium oxide (MgO); mica; polymers (e.g., PEN, PET, PEG, polyolefin, polypropylene, polyethylene, polycarbonate, PMMA, polyamide, vinyl, Kapton); ceramics; carbon; composites (e.g., fiberglass, Kevlar; carbon fiber); fabrics (e.g., cotton, nylon, silk, wool); wood; drywall; tiles (e.g. ceramic, composite, or clay); metal; steel; silver; gold; aluminum; magnesium; concrete; and combinations thereof.

As previously noted, an electrode (e.g., one of electrodes 3902 and 3912 of FIG. 2) may be either an anode or a cathode. In some embodiments, one electrode may function as a cathode, and the other may function as an anode. Either or both electrodes 3902 and 3912 may be coupled to leads, cables, wires, or other means enabling charge transport to and/or from the device 3900. An electrode may constitute any conductive material, and at least one electrode should be transparent or translucent to EM radiation, and/or be arranged in a manner that allows EM radiation to contact at least a portion of the active layer 3950. Suitable electrode materials may include any one or more of: indium tin oxide or tin-doped indium oxide (ITO); fluorine-doped tin oxide (FTO); cadmium oxide (CdO); zinc indium tin oxide (ZITO); aluminum zinc oxide (AZO); aluminum (Al); gold (Au); silver (Ag); calcium (Ca); chromium (Cr); copper (Cu); magnesium (Mg); titanium (Ti); steel; carbon (and allotropes thereof); doped carbon (e.g., nitrogen-doped); nanoparticles in core-shell configurations (e.g., silicon-carbon core-shell structure); and combinations thereof.

Mesoporous material (e.g., the material included in mesoporous layer 3904 of FIG. 2) may include any pore-containing material. In some embodiments, the pores may have diameters ranging from about 1 to about 100 nm; in other embodiments, pore diameter may range from about 2 to about 50 nm. Suitable mesoporous material includes any one or more of: any interfacial material and/or mesoporous material discussed elsewhere herein; aluminum (Al); bismuth (Bi); cerium (Ce); hafnium (Hf); indium (In); molybdenum (Mo); niobium (Nb); nickel (Ni); silicon (Si); titanium (Ti); vanadium (V); zinc (Zn); zirconium (Zr); an oxide of any one or more of the foregoing metals (e.g., alumina, ceria, titania, zinc oxide, zirconia, etc.); a sulfide of any one or more of the foregoing metals; a nitride of any one or more of the foregoing metals; and combinations thereof. In some embodiments, any material disclosed herein as an IFL may be a mesoporous material. In other embodiments, the device illustrated by FIG. 2 may not include a mesoporous material layer and include only thin-film, or “compact,” IFLs that are not mesoporous.

Photoactive material (e.g., first or second photoactive material 3906 or 3908 of FIG. 2) may comprise any photoactive compound, such as any one or more of silicon (for example, polycrystalline silicon, single-crystalline silicon, or amorphous silicon), cadmium telluride, cadmium sulfide, cadmium selenide, copper indium gallium selenide, copper indium selenide, copper zinc tin sulfide, gallium arsenide, germanium, germanium indium phosphide, indium phosphide, one or more semiconducting polymers (e.g., polythiophenes (e.g., poly(3-hexylthiophene) and derivatives thereof, or P3HT); carbazole-based copolymers such as polyheptadecanylcarbazole dithienylbenzothiadiazole and derivatives thereof (e.g., PCDTBT); other copolymers such as polycyclopentadithiophene-benzothiadiazole and derivatives thereof (e.g., PCPDTBT), polybenzodithiophenyl-thienothiophenediyl and derivatives thereof (e.g., PTB6, PTB7, PTB7-th, PCE-10); poly(triaryl amine) compounds and derivatives thereof (e.g., PTAA); polyphenylene vinylenes and derivatives thereof (e.g., MDMO-PPV, MEH-PPV), and combinations thereof.

In certain embodiments, photoactive material may instead or in addition comprise a dye (e.g., N719, N3, other ruthenium-based dyes). In some embodiments, a dye (of whatever composition) may be coated onto another layer (e.g., a mesoporous layer and/or an interfacial layer). In some embodiments, photoactive material may include one or more perovskite materials. Perovskite-material-containing photoactive substance may be of a solid form, or in some embodiments it may take the form of a dye that includes a suspension or solution comprising perovskite material. Such a solution or suspension may be coated onto other device components in a manner similar to other dyes. In some embodiments, solid perovskite-containing material may be deposited by any suitable means (e.g., vapor deposition, solution deposition, direct placement of solid material). Devices according to various embodiments may include one, two, three, or more photoactive compounds (e.g., one, two, three, or more perovskite materials, dyes, or combinations thereof). In certain embodiments including multiple dyes or other photoactive materials, each of the two or more dyes or other photoactive materials may be separated by one or more interfacial layers, or may be intermixed, at least in part.

As used herein, “charge transport material” refers to any material, solid, liquid, or otherwise, capable of collecting charge carriers (electrons or holes) and/or transporting charge carriers. Charge transport material (e.g., charge transport material of charge transport layer 3910 in FIG. 2) may include solid-state charge transport material (i.e., a colloquially labeled solid-state electrolyte), or it may include a liquid electrolyte and/or ionic liquid. In PV devices according to some embodiments, a charge transport material may be capable of transporting charge carriers to an electrode. Charge carriers may include holes (the transport of which could make the charge transport material just as properly labeled “hole transport material”) and electrons. Holes may be transported toward an anode, and electrons toward a cathode, depending upon placement of the charge transport material in relation to either a cathode or anode in a PV or other device. Suitable examples of charge transport material according to some embodiments may include any one or more of: perovskite material; I—/I3-; Co complexes; polythiophenes (e.g., poly(3-hexylthiophene) and derivatives thereof, or P3HT); carbazole-based copolymers such as polyheptadecanylcarbazole dithienylbenzothiadiazole and derivatives thereof (e.g., PCDTBT); other copolymers such as polycyclopentadithiophene-benzothiadiazole and derivatives thereof (e.g., PCPDTBT), polybenzodithiophenyl-thienothiophenediyl and derivatives thereof (e.g., PTB6, PTB7, PTB7-th, PCE-10); poly(triaryl amine) compounds and derivatives thereof (e.g., PTAA); Spiro-OMeTAD; polyphenylene vinylenes and derivatives thereof (e.g., MDMO-PPV, MEH-PPV); fullerenes and/or fullerene derivatives (e.g., C₆₀, PCBM); carbon nanotubes; graphite; graphene; carbon black; amorphous carbon; glassy carbon; carbon fiber; and combinations thereof. Charge transport material of some embodiments may be n- or p-type active, ambipolar, and/or intrinsic semi-conducting material. Charge transport material may be disposed proximate to one of the electrodes of a device. It may in some embodiments be disposed adjacent to an electrode, although in other embodiments an interfacial layer may be disposed between the charge transport material and an electrode (as shown, e.g., in FIG. 2 with the fifth interfacial layer 3911). In certain embodiments, the type of charge transport material may be selected based upon the electrode to which it is proximate. For example, if the charge transport material collects and/or transports holes, it may be proximate to an anode so as to transport holes to the anode. However, the charge transport material may instead be placed proximate to a cathode and be selected or constructed so as to transport electrons to the cathode.

As an example, FIG. 3 illustrates an embodiment of a tandem, two-terminal perovskite material device 3900a having a similar structure to perovskite material device 3900 illustrated by FIG. 2. FIG. 3 is a stylized diagram of a perovskite material device 3900a according to some embodiments including active layers 3906a and 3908a. One or both of active layers 3906a and 3908a may, in some embodiments, include any perovskite photoactive materials described above with respect to FIG. 2. In other embodiments, one or both of active layers 3906a and 3908a may include any photoactive material described herein, such as, thin film semiconductors (e.g., CdTe, CZTS, CIGS), photoactive polymers, dye sensitized photoactive materials, fullerenes, small molecule photoactive materials, and crystalline and polycrystalline semiconductor materials (e.g., silicon, GaAs, InP, Ge). In yet other embodiments, one or both of active layers 3906a and 3908a may include a light emitting diode (LED), field effect transistor (FET), thin film battery layer, or combinations thereof. In embodiments, one of active layers 3906a and 3908a may include a photoactive material and the other may include a LED, FET, thin film battery layer, or combinations thereof. Other layers illustrated of FIG. 3, such as layers 3901a, 3902a, 3903a, 3904a, 3905a, 3907a (i.e., a recombination layer), 3909a, 3910a, 3911a, 3912a, and 3913a, may be analogous to such corresponding layers as described herein with respect to FIG. 2.

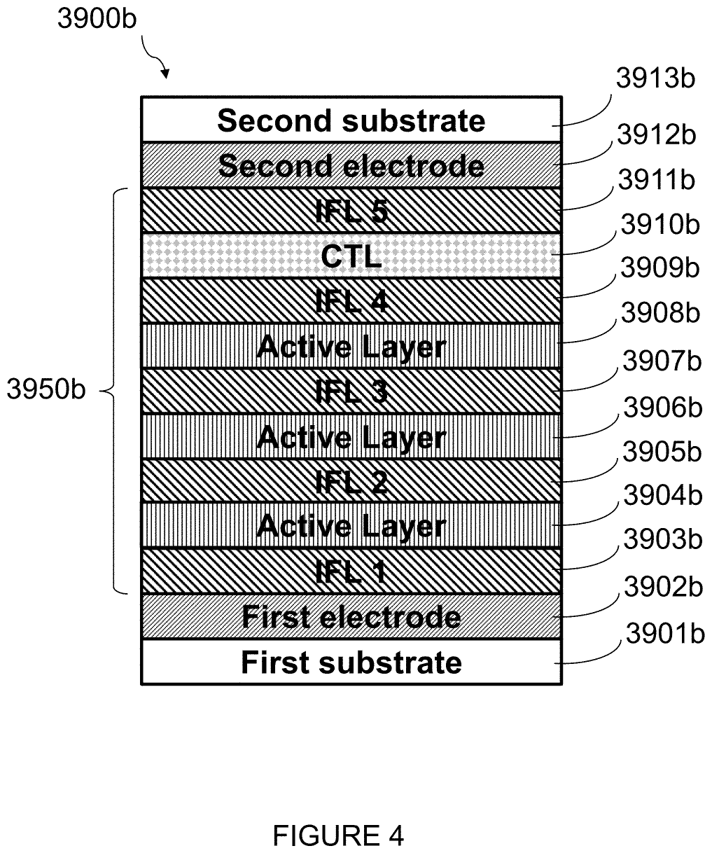

Additionally, in some embodiments, a perovskite material may have three or more active layers. As an example, FIG. 4 is a stylized diagram illustrating an embodiment of a tandem, two-terminal perovskite material device 3900b including three active layers and otherwise having a similar structure to perovskite material device 3900 illustrated by FIG. 2 FIG. 4 includes active layers 3904b, 3906b and 3908b. One or more of active layers 3904b, 3906b and 3908b may, in some embodiments, include any of the photoactive materials described above with respect to FIGS. 2 and 3. Other layers illustrated of FIG. 4, such as layers 3901b, 3902b, 3903b, 3904b, 3905b (i.e., a recombination layer), 3907b (i.e., a recombination layer), 3909b, 3910b, 3911b, 3912b, and 3913b, may be analogous to such corresponding layers as described herein with respect to FIGS. 2 and 3.

In some embodiments, a tandem PV device may be a four-terminal device, as shown in FIG. 9. The four-terminal device 2300 may include two sub-cells 2400 and 2500 which are electrically independent from the other. In some embodiments, the four-terminal device may include two sub-cells 2400 and 2500 that are mechanically stacked on top of each other but optically coupled, such that light that is transmitted through the front sub-cell 2400 reaches the back sub-cell 2500. The four-terminal PV 2300 includes a first substrate layer 2310, which may be glass (or a material similarly transparent to solar radiation) which allows solar radiation to transmit through the layer. The transparent layer of some embodiments may also be referred to as a superstrate or substrate, and it may comprise any one or more of a variety of rigid or flexible materials as discussed above.

The first PAM layer 2350 of the front sub-cell 2400 may be composed of electron donor or p-type material, and/or an electron acceptor or n-type material, and/or an ambipolar semiconductor, which exhibits both p- and n-type material characteristics, and/or an intrinsic semiconductor which exhibits neither n-type or p-type characteristics. Photoactive layer 2350 may in some embodiments, include any photoactive materials described above with respect to FIGS. 2-3. The active layer or, as depicted in FIG. 9, the photoactive layer 2350, is sandwiched between two electrically conductive electrode layers 2320 and 2370. As previously noted, an active layer of some embodiments need not necessarily be photoactive, although in the device shown in FIG. 63, it is. In FIG. 9, the electrode layer 6320 may be a transparent conductor such as a fluorine-doped tin oxide (FTO material) or other material as described herein. In other embodiments second substrate 2390 and second electrode 2370 may be transparent. The electrode layer 2370 may be a transparent conductor such as an indium zinc oxide (IZO material) material or other electrode material as described herein or is known in the art. The front sub-cell 2400 also includes interfacial layers (IFLs) 2330, 2340, 2350, 2355. The IFLs may include any suitable material described above. Although shown with two IFLs on either side of the photoactive layer 2350, the front sub-cell 2400 may include zero, one, two, three, four, five, or more interfacial layers on either side of the photoactive material layer 2350. An IFL according to some embodiments may be semiconducting in character and may be either intrinsic, ambipolar, p-type, or n-type, or it may be dielectric in character. In some embodiments, the IFLs on the cathode side of the device (e.g., IFLs 2355 and 2360 as shown in FIG. 9) may be n-type, and the IFLs on the anode side of the device (e.g., IFL 2330 and 2340 as shown in FIG. 9 may be p-type. In other embodiments, however, the cathode-side IFLs may be p-type and the anode-side IFLs may be n-type. The front sub-cell 2400 may be attached to electrical leads by electrodes 2320 and 2370 and a discharge unit, such as a battery, motor, capacitor, electric grid, or any other electrical load.

The back sub-cell 2500 of the PV device 2300 may have a similar or different architecture to the front sub-cell 2400. The back sub-cell 2500 may include a second photoactive material, and in some embodiments, may include any photoactive material described above with respect to FIGS. 2-4. In one example, the back sub-cell 2500 may include electrodes, IFLs, and other layers in the same or a different architecture as the front sub-cell 2400. One or both of photoactive layers of the front sub-cell 2400 and back sub-cell 2500 may, in some embodiments, include any photoactive materials described above with respect to FIGS. 2-4, or one may include a photoactive material and the other may include a LED, FET, thin film battery layer, or combinations thereof. Layers such as substrates, electrodes, and IFLs of the front sub-cell 2400 and back sub-cell may be analogous to such corresponding layers as described herein with respect to FIGS. 2-4, and may include any materials or configurations described as suitable for those corresponding layers.

A non-conductive layer 2380 may be disposed between, and adjacent to, the front-sub-cell 2400 and back sub-cell 2500. As used herein, “non-conductive layer” means layers that are electrically non-conductive, and is not intended to define any thermal properties of the non-conductive layer, which may be thermally conductive or insulating. In some embodiments, the non-conductive layer 2380 may include, but is not limited to an adhesive, epoxy, glass, laminate, wax, polymer, resin, elastomer, thermoset, or any combination thereof. In some embodiments, the non-conductive layer 6010 may include poly vinyl acetate, polyolefins, polystyrenes, polyglycols, polyorganic acids, natural rubber, synthetic rubber, polyesters, nylons, polyamides, polyaryls, polynucleic acids, polysaccharides, polyurethanes, acrylonitrile butadiene styrene, acrylic, acrylic polymers, acrylic resins, cross-linked porous resins, and any combination or derivative thereof. Examples of polymers suitable for certain embodiments include, but are not limited to poly(ethylene-vinyl acetate) (EVA), high-density polyethylene (HDPE), low-density polyethylene (LDPE), polypropylene (PP), polystyrene (PS), polyethylene glycol (PEG/PEO), poly(methyl methacrylate) (PMMA), polyoxymethylene (POM), poly(acrylonitrile butadiene styrene) (ABS), polyphenylene sulfide (PPS), polytetrafluoroethylene (PTFE), polyvinylidene difluoride (PVDF), polyvinyl chloride (PVC), poly(ethylene terephthalate (PET), polylactic acid (PLA), polycarbonate (PC), polyether ether ketone (PEEK), polybutylene terephthalate (PBT), butylene rubber, polyisoprene, polyurethane (PU), polydimethylsiloxane (PDMS), urea formaldehyde resin, an epoxy resin, phenol formaldehyde resin (PF), derivatives thereof, and any combination thereof. The configuration of the polymer backbone of the binding polymers may be isotactic, syndiotactic, or atactic. In one example, the non-conductive layer 2380 is transparent. In another example, the non-conductive layer 2380 is not transparent.

Additional, more specific, example embodiments of perovskite devices will be discussed in terms of further stylized depictions of example devices. The stylized nature of these depictions, FIGS. 2-4 and 9, similarly is not intended to restrict the type of device which may in some embodiments be constructed in accordance with any one or more of FIGS. 2-4 and 9. That is, the architectures exhibited in FIGS. 2-4 and 9 may be adapted so as to provide the BHJs, batteries, FETs, hybrid PV batteries, serial multi-cell PVs, parallel multi-cell PVs and other similar devices of other embodiments of the present disclosure, in accordance with any suitable means (including both those expressly discussed elsewhere herein, and other suitable means, which will be apparent to those skilled in the art with the benefit of this disclosure).

Formation of the Perovskite Material Active Layer

In certain embodiments, the perovskite material may be deposited as an active layer in a PV device by, for example, blade coating, drop casting, spin casting, slot-die printing, screen printing, or ink-jet printing onto a substrate layer using the steps described below.

First, a lead halide precursor ink is formed. An amount of lead halide may be massed in a clean, dry vessel in a controlled atmosphere environment (e.g., a controlled atmosphere box with glove-containing portholes allows for materials manipulation in an air-free environment). Suitable lead halides include, but are not limited to, lead (II) iodide, lead (II) bromide, lead (II) chloride, and lead (II) fluoride. The lead halide may comprise a single species of lead halide or it may comprise a lead halide mixture in a precise ratio. In certain embodiments, the lead halide mixture may comprise any binary, ternary, or quaternary ratio of 0.001-100 mol % of iodide, bromide, chloride, or fluoride. In one embodiment, the lead halide mixture may comprise lead (II) chloride and lead (II) iodide in a ratio of about 10:90 mol:mol. In other embodiments, the lead halide mixture may comprise lead (II) chloride and lead (II) iodide in a ratio of about 5:95, about 7.5:92.5, or about 15:85 mol:mol.

Alternatively, other lead salt precursors may be used in conjunction with or in lieu of lead halide salts to form the precursor ink. Suitable precursor salts may comprise any combination of lead (II) or lead(IV) and the following anions: nitrate, nitrite, carboxylate, acetate, acetonyl acetonate, formate, oxalate, sulfate, sulfite, thiosulfate, phosphate, tetrafluoroborate, hexafluorophosphate, tetra(perfluorophenyl) borate, hydride, oxide, peroxide, hydroxide, nitride, arsenate, arsenite, perchlorate, carbonate, bicarbonate, chromate, dichromate, iodate, bromate, chlorate, chlorite, hypochlorite, hypobromite, cyanide, cyanate, isocyanate, fulminate, thiocyanate, isothiocyanate, azide, tetracarbonylcobaltate, carbamoyldicyanomethanide, dicyanonitrosomethanide, dicyanamide, tricyanomethanide, amide, and permanganate.

The precursor ink may further comprise a lead (II) or lead (IV) salt in mole ratios of 0 to 100% to the following metal ions Be, Mg, Ca, Sr, Ba, Fe, Cd, Co, Ni, Cu, Ag, Au, Hg, Sn, Ge, Ga, Pb, In, Tl, Sb, Bi, Ti, Zn, Cd, Hg, and Zr as a salt of the aforementioned anions.

A solvent may then be added to the vessel to dissolve the lead solids to form the lead halide precursor ink. Suitable solvents include, but are not limited to, dry N-cyclohexyl-2-pyrrolidone, alkyl-2-pyrrolidone, dimethylformamide, dialkylformamide, dimethylsulfoxide (DMSO), methanol, ethanol, propanol, butanol, tetrahydrofuran, formamide, tert-butylpyridine, pyridine, alkylpyridine, pyrrolidine, chlorobenzene, dichlorobenzene, dichloromethane, chloroform, alkylnitrile, arylnitrile, acetonitrile, alkoxylalcohols, alkoxyethanol, 2-methoxyethanol, glycols, propylene glycol, ethylene glycol, and combinations thereof. In one embodiment, the lead solids are dissolved in dry dimethylformamide (DMF). In some embodiments, the solvent may further comprise 2-methoxyethanol and acetonitrile. In some embodiments, 2-methoxyethanol and acetonitrile may be added in a volume ratio of from about 25:75 to about 75:25, or at least 25:75. In certain embodiments, the solvent may include a ratio of 2-methoxyethanol and acetonitrile to DMF of from about 1:100 to about 1:1, or from about 1:100 to about 1:5, on a volume basis. In certain embodiments, the solvent may include a ratio of 2-methoxyethanol and acetonitrile to DMF of at least about 1:100 on a volume basis.

In certain embodiment, the lead solids may be dissolved at a temperature between about 20° C. to about 150° C. In one embodiment, the lead halide solids are dissolved at about 85° C. The lead solids may be dissolved for as long as necessary to form a solution, which may take place over a time period up to about 72 hours. The resulting solution forms the base of the lead halide precursor ink. In some embodiments, the lead halide precursor ink may have a lead halide concentration between about 0.001M and about 10M, or about 1 M.

Optionally, certain additives may be added to the lead halide precursor ink to affect the final perovskite crystallinity and stability. In some embodiments, the lead halide precursor ink may further comprise an amino acid (e.g., 5-aminovaleric acid, histidine, glycine, lysine), an amino acid hydrohalide (e.g., 5-amino valeric acid hydrochloride), an IFL surface-modifying (SAM) agent (such as those discussed earlier in the specification), or a combination thereof. Amino acids suitable for lead halide precursor inks may include, but are not limited to α-amino acids, β-amino acids, γ-amino acids, δ-amino acids, and any combination thereof. In one embodiment, formamidinium chloride may be added to the lead halide precursor ink. In other embodiments, the halide of any cation discussed earlier in the specification may be used. In some embodiments, combinations of additives may be added to the lead halide precursor ink including, for example, the combination of formamidinium chloride and 5-amino valeric acid hydrochloride.

The additives, including, in some embodiments, formamidinium chloride and/or 5-amino valeric acid hydrochloride. may be added to the lead halide precursor ink at various concentrations depending on the desired characteristics of the resulting perovskite material. In one embodiment, the additives may be added in a concentration of about 1 nM to about 1 M, from. about 1 μM to about 1 M, or from about 1 μM to about 1 mM.

Optionally, in certain embodiments, water may be added to the lead halide precursor ink. By way of explanation, and without limiting the disclosure to any particular theory or mechanism, the presence of water affects perovskite thin-film crystalline growth. Under normal circumstances, water may be absorbed as vapor from the air. However, it is possible to control the perovskite PV crystallinity through the direct addition of water to the lead halide precursor ink in specific concentrations. Suitable water includes distilled, deionized water, or any other source of water that is substantially free of contaminants (including minerals). It has been found, based on light I-V sweeps, that the perovskite PV light-to-power conversion efficiency may nearly triple with the addition of water compared to a completely dry device.

The water may be added to the lead halide precursor ink at various concentrations depending on the desired characteristics of the resulting perovskite material. In one embodiment, the water may be added in a concentration of about 1 nL/mL to about 1 mL/mL, from about 1 μL/mL to about 0.1 mL/mL, or from about 1 μL/mL to about 20 pL/mL.

The lead halide precursor ink may then be deposited on the desired substrate. Suitable substrate layers may include any of the substrate layers identified earlier in this disclosure. As noted above, the lead halide precursor ink may be deposited through a variety of means, including but not limited to, drop casting, spin coating (spin casting), slot-die printing, ink-jet printing, gravure printing, screen printing, sputtering, PE-CVD, atomic-layer deposition, thermal evaporation, spray coating, and any combination thereof. In certain embodiments, the lead halide precursor ink may be spin-coated onto the substrate at a speed of about 500 rpm to about 10,000 rpm for a time period of about 5 seconds to about 600 seconds. In one embodiment, the lead halide precursor ink may be spin-coated onto the substrate at about 3000 rpm for about 30 seconds. The lead halide precursor ink may be deposited on the substrate at an ambient atmosphere in a humidity range of about 0% relative humidity to about 50% relative humidity. The lead halide precursor ink may then be allowed to dry in a substantially water-free atmosphere, i.e., less than 30% relative humidity, to form a thin film.

The thin film may then be thermally annealed for a time period up to about 24 hours at a temperature of about 20° C. to about 300° C. In one embodiment, the thin film may be thermally annealed for about ten minutes at a temperature of about 50° C. The perovskite material active layer may then be completed by a conversion process in which the precursor film is submerged or rinsed with a solution comprising a solvent or mixture of solvents (e.g., DMF, isopropanol, methanol, ethanol, butanol, chloroform chlorobenzene, dimethylsulfoxide, water) and salt (e.g., methylammonium iodide, formamidinium iodide, guanidinium iodide, 1,2,2-triaminovinylammonium iodide, 5-aminovaleric acid hydroiodide) in a concentration between 0.001M and 10M. In certain embodiments, the thin films may also be thermally post-annealed in the same fashion as in the first line of this paragraph.

In some embodiments, a lead salt precursor may be deposited onto a substrate to form a lead salt thin film. The substrate may have a temperature about equal to ambient temperature or have a controlled temperature between 0° C. and 500° C. The lead salt precursor may be deposited by any of the methods discussed above with respect to the lead halide precursor ink. In certain embodiments, the deposition of the lead salt precursor may comprise sheet-to-sheet or roll-to-roll manufacturing methodologies. Deposition of the lead salt precursor may be performed in a variety of atmospheres at ambient pressure or at pressures less than atmospheric or ambient (e.g., 1 mTorr to 500 mTorr). The deposition atmosphere may comprise ambient air, a controlled humidity environment (e.g., 0-100 g H₂O/m³ of gas), pure argon, pure nitrogen, pure oxygen, pure hydrogen, pure helium, pure neon, pure krypton, pure CO₂ or any combination of the preceding gases. A controlled humidity environment may include an environment in which the absolute humidity or the % relative humidity is held at a fixed value, or in which the absolute humidity or the % relative humidity varies according to predetermined set points or a predetermined function. In particular embodiments, deposition may occur in a controlled humidity environment having a % relative humidity greater than or equal to 0% and less than or equal to 50%. In other embodiments, deposition may occur in a controlled humidity environment containing greater than or equal to 0 g H₂O/m³ gas and less than or equal to 20 g H₂O/m³ gas. Unless described as otherwise, any annealing or deposition step described herein may be carried out under the preceding conditions.

The lead salt precursor may be a liquid, a gas, solid, or combination of these states of matter such as a solution, suspension, colloid, foam, gel, or aerosol. In some embodiments, the lead salt precursor may be a solution containing one or more solvents. For example, the lead salt precursor may contain one or more of N-cyclohexyl-2-pyrrolidone, alkyl-2-pyrrolidone, dimethylformamide, dialkylformamide, dimethylsulfoxide (DMSO), acetonitrile, methanol, ethanol, propanol, butanol, tetrahydrofuran, formamide, tert-butylpyridine, pyridine, alkylpyridine, pyrrolidine, chlorobenzene, dichlorobenzene, dichloromethane, chloroform, and combinations thereof. The lead salt precursor may comprise a single lead salt (e.g., lead (II) iodide, lead (II) thiocyanate) or any combination of those disclosed herein (e.g., PbI₂+PbCl₂; PbI₂+Pb(SCN)₂). The lead salt precursor may also contain one or more additives such as an amino acid (e.g., 5-aminovaleric acid hydroiodide), 1,8-diiodooctane, 1,8-dithiooctane, formamidinium halide, acetic acid, trifluoroacetic acid, a methylammonium halide, or water. The lead salt precursor may be allowed to dry in a substantially water-free atmosphere, i.e., less than 30% relative humidity, to form a thin film. The lead salt thin film may then be thermally annealed for the same amount of times and under the same conditions as discussed above with respect to the lead halide precursor ink thin film. The annealing environment may have the same pressures and atmosphere as the lead salt deposition environments and conditions discussed above. In particular embodiments, annealing may occur in a controlled humidity environment having a % relative humidity greater than or equal to 0% and less than or equal to 50%. In other embodiments, annealing may occur in a controlled humidity environment containing greater than or equal to 0 g H₂O/m³ gas and less than or equal to 20 g H₂O/m³ gas

After the lead salt precursor is deposited, a second salt precursor (e.g., formamidinium iodide, formamidinium thiocyanate, guanidinium thiocyanate) may be deposited onto the lead salt thin film, where the lead salt thin film may have a temperature about equal to ambient temperature or have a controlled temperature between 0° C. and 500° C. The second salt precursor, in some embodiments, may be deposited at ambient temperature or at elevated temperature between about 25° C. and 125° C. The second salt precursor may be deposited by any of the methods discussed above with respect to the lead halide precursor ink. Deposition of the second salt precursor may be in the same environments and under the same conditions as discussed above with respect to the first salt precursor.

In some embodiments the second salt precursor may be a solution containing one or more of the solvents (e.g., one or more of the solvents discussed above with respect to the first lead salt precursor).

After deposition of the lead salt precursor and second salt precursor, the substrate may be annealed. Annealing the substrate may convert the lead salt precursor and second salt precursor to a perovskite material, (e.g. FAPbI₃, GAPb(SCN)₃, FASnI₃). The annealing may occur in the same environment and under the same conditions as the lead salt deposition environments and conditions discussed above. In particular embodiments, annealing may occur in a controlled humidity environment having a % relative humidity greater than or equal to 0% and less than or equal to 50%. In other embodiments, annealing may occur in a controlled humidity environment containing greater than or equal to 0 g H₂O/m³ gas and less than or equal to 20 g H₂O/m³ gas. In some embodiments, annealing may occur at a temperature greater than or equal to 50° C. and less than or equal to 300° C.

For example, in a particular embodiment, a FAPbI₃ perovskite material may be formed by the following process. First a lead (II) halide precursor comprising about a 90:10 mole ratio of PbI₂ to PbCl₂ dissolved in anhydrous DMF may be deposited onto a substrate by spin-coating or slot-die printing. The lead halide precursor ink may be allowed to dry in a substantially water-free atmosphere, i.e., less than 30% relative humidity, for approximately one hour (+15 minutes) to form a thin film. The thin film may be subsequently thermally annealed for about ten minutes at a temperature of about 50° C. (±10° C.). Next, a formamidinium iodide precursor comprising a 25-60 mg/mL concentration of formamidinium iodide dissolved in anhydrous isopropyl alcohol may be deposited onto the lead halide thin film by spin coating or slot-die printing. After depositing the lead halide precursor and formamidinium iodide precursor, the substrate may be annealed at about 25% relative humidity (about 4 to 7 g H₂O/m³ air) and between about 125° C. and 200° C. to form a formamidinium lead iodide (FAPbI₃) perovskite material.

In another embodiment, a perovskite material may comprise C′CPbX₃, where C′ is one or more Group 1 metals (e.g., Li, Na, K, Rb, Cs). In a particular embodiment M′ may be cesium (Cs). In yet other embodiments, a perovskite material may comprise C′ᵥC_{w}Pb_{y}X_{z}, where C′ is one or more Group 1 metals and v, w, y, and z represent real numbers between 1 and 20. In certain embodiments, the perovskite material may be deposited as an active layer in a PV device by, for example, drop casting, spin casting, gravure coating, blade coating, reverse gravure coating, slot-die printing, screen printing, or ink-jet printing onto a substrate layer.

First, a lead halide solution is formed. The lead halide solution may be prepared in any of the same methods and with similar compositions as the lead halide precursor ink discussed above. Other lead salt precursors (e.g., those discussed above with respect to lead halide precursor inks) may be used in conjunction with or in lieu of lead halide salts to form a lead salt solution.

Next, a Group 1 metal halide solution is formed. An amount of Group 1 metal halide may be massed in a clean, dry vessel in a controlled atmosphere environment. Suitable Group 1 metal halides include, but are not limited to, cesium iodide, cesium bromide, cesium chloride, cesium fluoride, rubidium iodide, rubidium bromide, rubidium chloride, rubidium fluoride, lithium iodide, lithium bromide, lithium chloride, lithium fluoride, sodium iodide, sodium bromide, sodium chloride, sodium fluoride, potassium iodide, potassium bromide, potassium chloride, potassium fluoride. The Group 1 metal halide may comprise a single species of Group 1 metal halide or it may comprise a Group 1 metal halide mixture in a precise ratio.

Alternatively, other Group 1 metal salt precursors may be used in conjunction with or in lieu of Group 1 metal halide salts to form a Group 1 metal salt solution. Suitable precursor Group 1 metal salts may comprise any combination of Group 1 metals and the following anions: nitrate, nitrite, carboxylate, acetate, formate, oxalate, sulfate, sulfite, thiosulfate, phosphate, tetrafluoroborate, hexafluorophosphate, tetra(perfluorophenyl) borate, hydride, oxide, peroxide, hydroxide, nitride, arsenate, arsenite, perchlorate, carbonate, bicarbonate, chromate, dichromate, iodate, bromate, chlorate, chlorite, hypochlorite, hypobromite, cyanide, cyanate, isocyanate, fulminate, thiocyanate, isothiocyanate, azide, tetracarbonylcobaltate, carbamoyldicyanomethanide, dicyanonitrosomethanide, dicyanamide, tri cyanomethanide, amide, and permanganate.

A solvent may then be added to the vessel to dissolve the Group 1 metal halide solids to form the Group 1 metal halide solution. Suitable solvents include, but are not limited to, dry N-cyclohexyl-2-pyrrolidone, alkyl-2-pyrrolidone, dimethylformamide (DMF), dialkylformamide, dimethylsulfoxide (DMSO), acetonitrile, methanol, ethanol, propanol, butanol, tetrahydrofuran, formamide, tert-butylpyridine, pyridine, alkylpyridine, pyrrolidine, chlorobenzene, dichlorobenzene, dichloromethane, chloroform, and combinations thereof. In one embodiment, the lead solids are dissolved in dry dimethylsulfoxide (DMSO). The Group 1 metal halide solids may be dissolved at a temperature between about 20° C. to about 150° C. In one embodiment, the Group 1 metal halide solids are dissolved at room temperature (i.e., about 25° C.). The Group 1 metal halide solids may be dissolved for as long as necessary to form a solution, which may take place over a time period up to about 72 hours. The resulting solution forms the Group 1 metal halide solution. In some embodiments, the Group 1 metal halide solution may have a Group 1 metal halide concentration between about 0.001M and about 10M, or about 1 M. In some embodiments, the Group 1 metal halide solution may further comprise an amino acid (e.g., 5-aminovaleric acid, histidine, glycine, lysine), an amino acid hydrohalide (e.g., 5-amino valeric acid hydrochloride), an IFL surface-modifying (SAM) agent (such as those discussed earlier in the specification), or a combination thereof.

Next, the lead halide solution and the Group 1 metal halide solution are mixed to form a thin-film precursor ink. The lead halide solution and Group 1 metal halide solution may be mixed in a ratio such that the resulting thin-film precursor ink has a molar concentration of the Group 1 metal halide that is between 0% and 25% of the molar concentration of the lead halide. In particular embodiments, the thin-film precursor ink may have a molar concentration of the Group 1 metal halide that is 1%, 5%, 10%, 15%, 20%, or 25% of the molar concentration of the lead halide. In some embodiments the lead halide solution and the Group 1 metal halide solution may be stirred or agitated during or after mixing.

The thin-film precursor ink may then be deposited on the desired substrate through any of the deposition means discussed above. Suitable substrate layers may include any of the substrate layers identified earlier in this disclosure. In certain embodiments, the thin-film precursor ink may be spin-coated onto the substrate at a speed of about 500 rpm to about 10,000 rpm for a time period of about 5 seconds to about 600 seconds. In one embodiment, the thin-film precursor ink may be spin-coated onto the substrate at about 3000 rpm for about 30 seconds. The thin-film precursor ink may be deposited on the substrate at an ambient atmosphere in a humidity range of about 0% relative humidity to about 50% relative humidity. The thin-film precursor ink may then be allowed to dry in a substantially water-free atmosphere, i.e., less than 30% relative humidity or 7 g H₂O/m3, to form a thin film.

The thin film can then be thermally annealed for a time period up to about 24 hours at a temperature of about 20° C. to about 300° C. In one embodiment, the thin film may be thermally annealed for about ten minutes at a temperature of about 50° C. The perovskite material active layer may then be completed by a conversion process in which the precursor film is submerged or rinsed with a salt solution comprising a solvent or mixture of solvents (e.g., DMF, isopropanol, methanol, ethanol, butanol, chloroform chlorobenzene, dimethylsulfoxide, water) and salt (e.g., methylammonium iodide, formamidinium iodide, guanidinium iodide, 1,2,2-triaminovinylammonium iodide, 5-aminovaleric acid hydroiodide) in a concentration between 0.001M and 10M. In certain embodiments, the perovskite material thin films can also be thermally post-annealed in the same fashion as in the first line of this paragraph.

In some embodiments, the salt solution may be prepared by massing the salt in a clean, dry vessel in a controlled atmosphere environment. Suitable salts include, but are not limited to, methylammonium iodide, formamidinium iodide, guanidinium iodide, imidazolium iodide, ethene tetramine iodide, 1,2,2-triaminovinylammonium iodide, and 5-aminovaleric acid hydroiodide. Other suitable salts may include any organic cation described above in the section entitled “Perovskite Material.” The salt may comprise a single species of salt or it may comprise a salt mixture in a precise ratio. Next, a solvent may then be added to the vessel to dissolve the salt solids to form the salt solution. Suitable solvents include those listed in the preceding paragraph, and combinations thereof. In one embodiment, formamidinium iodide salt solids are dissolved in isopropanol. The salt solids may be dissolved at a temperature between about 20° C. to about 150° C. In one embodiment, the salt solids are dissolved at room temperature (i.e. about 25° C.). The salt solids may be dissolved for as long as necessary to form a solution, which may take place over a time period up to about 72 hours. The resulting solution forms the salt solution. In some embodiments, the salt solution may have a salt concentration between about 0.001M and about 10M. In one embodiment, the salt solution has a salt concentration of about 1 M.

For example, using the process described above with a lead (II) iodide solution, a cesium iodide solution, and a methylammonium (MA) iodide salt solution may result in a perovskite material having the a formula of CsᵢMA₁₋ᵢPbI₃, where i equals a number between 0 and 1. As another example, using a lead (II) iodide solution, a rubidium iodide solution, and a formamidinium (FA) iodide salt solution may result in a perovskite material having the a formula of RbᵢFA₁₋ᵢPbI₃, where i equals a number between 0 and 1. As another example, using a lead (II) iodide solution, a cesium iodide solution, and a formamidinium (FA) iodide salt solution may result in a perovskite material having the a formula of CsᵢFA₁₋ᵢPbI₃, where i equals a number between 0 and 1. As another example, using a lead (II) iodide solution, a potassium iodide solution, and a formamidinium (FA) iodide salt solution may result in a perovskite material having the a formula of KᵢFAᵢPbI₃, where i equals a number between 0 and 1. As another example, the using a lead (II) iodide solution, a sodium iodide solution, and a formamidinium (FA) iodide salt solution may result in a perovskite material having the a formula of NaᵢFA₁₋ᵢPbI₃, where i equals a number between 0 and 1. As another example, the using a lead (II) iodide-lead (II) chloride mixture solution, a cesium iodide solution, and a formamidinium (FA) iodide salt solution may result in a perovskite material having the a formula of CsᵢFA₁₋ᵢPbI_{3-y}Cl_{y}, where i equals a number between 0 and 1 and y represents a number between 0 and 3.

In a particular embodiment, the lead halide solution as described above may have a ratio of 90:10 of PbI₂ to PbCl₂ on a mole basis. A cesium iodide (CsI) solution may be added to the lead halide solution by the method described above to form a thin film precursor ink with 10 mol % CsI. A FAPbI₃ perovskite material may be produced according to the method described above using this thin film precursor solution. The addition of cesium ions through the CsI solution as described above may cause chloride anions and cesium atoms to incorporate into the FAPbI₃ crystal lattice. This may result in a greater degree of lattice contraction compared to addition of cesium or rubidium ions as described above without addition of chloride ions. Table 1 below shows lattice parameters for FAPbI₃ perovskite materials with 10 mol % rubidium and 20 mol % chloride (e.g. 10 mol % PbCl2), 10 mol % cesium, and 10 mol % cesium with 20 mol % chloride, wherein the mol % concentration represents the concentration of the additive with respect to the lead atoms in the lead halide solution. As can be seen in Table 1, the FAPbI₃ perovskite material with cesium and chloride added has smaller lattice parameters than the other two perovskite material samples.

TABLE 1

| | (001) | (002) |
|---|---|---|
| Sample Details | d-spacing | d-spacing |
| 10 mol % RbI + | 6.3759(15) | 3.1822(5) |
| 10 mol % PbCl₂ | | |
| 10 mol % CsI + | 6.3425(13) | 3.1736(8) |
| 0 mol % PbCl₂ | | |
| 10 mol % CsI + | 6.3272(13) | 3.1633(4) |
| 10 mol % PbCl₂ | | |

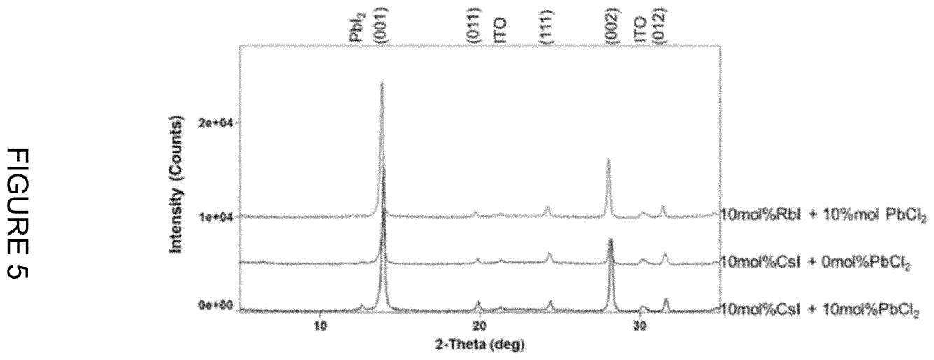

Additionally, data shows that the FAPbI₃ perovskite material with rubidium, cesium and/or chloride added has a Pm3-m cubic structure. FAPbI₃ perovskites with up to and including 10 mol % Rb and 10 mol % Cl, or 10 mol % Cs, or 10 mol % Cs and 10 mol % Cl have been observed to maintain a cubic Pm3-m cubic crystal structure. FIG. 5 shows x-ray diffraction patterns corresponding to each of the samples presented in Table 1. Tables 2-4 provide the x-ray diffraction peaks and intensity for the three perovskite materials shown in Table 1. The data were collected at ambient conditions on a Rigaku Miniflex 600 using a Cu Kα radiation source at a scan rate of 1.5 degrees 2θ/min.

TABLE 2
10 mol % RbI + 10 mol % PbCl2

| 2-theta | d | Height | Peak Identity |
|---|---|---|---|
| (deg) | (ang.) | (cps) | (phase, miller index) |
| | | | PbI2, (001) |
| 13.878(3) | 6.3759(15) | 12605(126) | Perovskite, (001) |
| 19.707(15) | 4.501(3) | 489(25) | Perovskite, (011) |
| 21.320(14) | 4.164(3) | 286(19) | ITO, (112) |
| 24.227(19) | 3.671(3) | 1022(36) | Perovskite, (111) |
| 28.017(4) | 3.1822(5) | 5683(84) | Perovskite, (002) |
| 30.13(4) | 2.964(4) | 344(21) | ITO, (112) |
| 31.403(14) | 2.8464(13) | 913(34) | Perovskite, (012) |

TABLE 3
10 mol % CsI & 0 mol % PbCl2

| 2-theta | d | Height | Peak Identity |
|---|---|---|---|
| (deg) | (ang.) | (cps) | phase (miller index) |
| 12.614(14) | 7.012(8) | 99(11) | PbI2, (001) |
| 13.952(3) | 6.3425(13) | 4921(78) | Perovskite, (001) |
| 19.826(12) | 4.475(3) | 392(22) | Perovskite, (011) |
| 21.274(14) | 4.173(3) | 281(19) | ITO, (112) |
| 24.333(15) | 3.655(2) | 1031(36) | Perovskite, (111) |
| 28.094(7) | 3.1736(8) | 2332(54) | Perovskite, (002) |
| 30.15(4) | 2.962(4) | 364(21) | ITO, (112) |
| 31.531(12) | 2.8351(10) | 941(34) | Perovskite, (012) |

TABLE 4
10 mol % CsI & 10 mol % PbCl2

| 2-theta | d | Height | Peak Identity |
|---|---|---|---|
| (deg) | (ang.) | (cps) | phase (miller index) |
| 12.635(6) | 7.000(3) | 395(22) | PbI2, (001) |
| 13.985(3) | 6.3272(13) | 13692(131) | Perovskite, (001) |
| 19.867(11) | 4.465(2) | 807(32) | Perovskite, (011) |
| 21.392(13) | 4.150(2) | 254(18) | ITO, (112) |
| 24.41(2) | 3.643(3) | 918(34) | Perovskite, (111) |
| 28.188(4) | 3.1633(4) | 6797(92) | Perovskite, (002) |
| 30.14(4) | 2.963(4) | 348(21) | ITO, (112) |
| 31.633(15) | 2.8262(13) | 1027(36) | Perovskite, (012) |

A geometrically expected x-ray diffraction pattern for cubic Pm3-m material with a lattice constant=6.3375 Å under Cu-Kα radiation is shown in Table 5. As can be seen from the data, the perovskite materials produced with 10 mol % Rb and 10 mol % Cl, 10 mol % Cs, and 10% Cs and 10% Cl each have diffraction patterns conforming to the expected pattern for a cubic, Pm3-m perovskite material.

TABLE 5
Geometrically Expected Diffraction Pattern for Cubic
Pm3-m, lattice constant = 6.3375Å; Cu-Kα Radiation)

| | d-spacing | |
|---|---|---|
| 2-Theta (degrees) | (angstroms) | Miller Index |
| 13.963 | 6.3375 | (0 0 1) |
| 19.796 | 4.4813 | (0 1 1) |
| 24.306 | 3.659 | (1 1 1) |
| 28.138 | 3.1688 | (0 0 2) |
| 31.541 | 2.8342 | (0 1 2) |

### Method of Forming Perovskite Material Layers

Methods for producing a perovskite material is described below. Such methods may apply to any suitable perovskite material, including those discussed in the present disclosure in the sections titled “Perovskite Material” and “Formation of the Perovskite Material Active Layer”.

In certain embodiments, the method comprises: forming a lead halide precursor thin film, wherein forming the lead halide precursor thin film comprises: depositing a lead halide precursor ink onto a substrate; drying the lead halide precursor ink to form a first thin film; and annealing the first thin film. In some embodiments, the method further comprises forming a perovskite material layer, wherein forming the perovskite material layer comprises steps of: depositing a benzylammonium halide precursor ink onto the first thin film; drying the benzylammonium halide precursor ink; depositing a formamidinium halide precursor ink onto the benzylammonium halide precursor ink; drying the formamidinium halide precursor ink to form a second thin film; and annealing the second thin film.

First, a lead halide precursor ink is formed as described in paragraphs [0061]-[0069]. Next, the lead halide precursor ink (e.g., PbI₂ solution) may then be deposited on the desired substrate. Suitable substrate layers may include any of the substrate layers identified earlier in this disclosure. In certain embodiments, the lead halide precursor ink (e.g., PbI₂ solution) is deposited on an NiO thin film. A method for preparing the NiO thin film is described below.

Although referred to herein as NiO and/or nickel oxide, it should be noted that various ratios of nickel and oxygen may be used in forming nickel oxide. Thus, although some embodiments discussed herein are described with reference to NiO, such description is not intended to define a required ratio of nickel in oxygen. Rather, embodiments may include any one or more nickel-oxide compounds, each having an nickel oxide ratio according to NixOy, where x may be any value, integer or non-integer, between approximately 1 and 100. In some embodiments, x may be between approximately 1 and 3 (and, again, need not be an integer). Likewise, y may be any value, integer or non-integer, between 0.1 and 100. In some embodiments, y may be between 2 and 4 (and, again, need not be an integer). In addition, various crystalline forms of NixOy may be present in various embodiments, such as alpha, gamma, and/or amorphous forms.

A NiO precursor ink of the present disclosure may include a nickel nitrate and/or nickel acetate and may include a metal nitrate or metal acetate dissolved in a solvent mixture comprising a diol, water, and an alcohol-amine. In some embodiments, the NiO precursor ink includes nickel nitrate and one or more metal acetates dissolved in a solvent mixture comprising a diol, water, and an alcohol. In other embodiments, the NiO precursor ink includes nickel acetate and one or more metal nitrates, and does not include nickel nitrate, dissolved in a solvent mixture comprising a diol, water, and an alcohol-amine.

In some embodiments, the NiO precursor ink of the present disclosure may include other metals as described herein. These metals may act as dopants in the resulting nickel oxide thin film, resulting in hole-transporting or electron-transporting nickel oxide thin films, depending on the metal dopant(s) included in the NiO precursor ink. Examples of compounds to prepare the NiO precursor ink may include, but are not limited to, anhydrous nickel nitrate, nickel nitrate hexahydrate, nickel nitrate nonahydrate, nickel nitrate tetrahydrate, nickel nitrate dihydrate, and any derivative hydrates of nickel nitrate, and anhydrous nickel acetate, nickel acetate dihydrate, nickel acetate tetrahydrate, and anhydrous copper nitrate, copper nitrate monohydrate, copper nitrate sesquihydrate, copper nitrate hemipentahydrate, copper nitrate trihydrate, copper nitrate hexahydrate, and any derivative hydrates of copper nitrate, and anhydrous copper acetate, copper acetate monohydrate. In certain embodiments, the NiO precursor inks of the present disclosure may be formulated using a mixture of nickel nitrate (Ni(NO₃)₂), a metal acetate, and water in a diol solvent with an alcohol-amine additive. In certain embodiments, the metal acetate may be one or more of nickel acetate (Ni(CH₃CO₂)₂) or copper acetate (Cu(CH₃CO₂)₂), and amines, diamines, and acetylacetone (and derivatives thereof) may also be included in the NiO precursor ink.

In some embodiments, a nickel oxide precursor ink may be formulated with a mixture of nickel nitrate, nickel acetate, water, and ethanol amine in an ethylene glycol solvent. In other embodiments, a nickel oxide precursor ink may be formulated with a mixture of nickel nitrate, nickel acetate, water, ethanol amine, and acetylacetone in an ethylene glycol solvent. In yet other embodiments, a nickel oxide precursor ink may be formulated with a mixture of nickel nitrate, copper acetate, water, and ethanol amine in an ethylene glycol solvent. In yet other embodiments, a nickel oxide precursor ink may be formulated with a mixture of nickel nitrate, copper acetate, water, ethanol amine, and acetylacetone in an ethylene glycol solvent. In other embodiments, a nickel oxide precursor ink may be formulated with a mixture of nickel nitrate, a metal acetate having the formula M(CH₃CO₂)_{y} wherein M may be any metal (for example, Cu, Li, Na, K, Rb, Cs, Be, Mg, Ca, Sr, Ba, Sc, Y, Ti, Zr, Hf, V, Nb, Ta, Cr, Mo, W, Mn, Re, Fe, Ru, Os, Co, Rh, Ir, Pd, Pt, Cu, Ag, Au, Zn, Cd, Hg, B, Al, Ga, In, Tl, Si, Ge, Sn, Pb, As, Sb, Bi, Se, Te, La, Ce, Pr, Nd, Sm, Er, Gd, Tb, Dy, Ho, Er, Ym, Yb, Lu, Ac, Th, Pa, and U) and y corresponds to the oxidation state of the metal M (e.g., y=2 where M is Cu²+ and y=6 where M is W⁶⁺), water, and ethanol amine in an ethylene glycol solvent. In some embodiments, hydrates of nickel nitrate (e.g., Ni(NO₃)₂.aH₂O), nickel acetate (e.g., Ni(CH₃CO₂)₂.bH₂O), copper acetate (e.g., Cu(CH₃CO₂)₂.cH₂O), or metal acetate (e.g., M(CH₃CO₂)_{y}.dH2O) may be included in the nickel oxide precursor ink formulation as described herein, where a, b, c, and d in the forgoing formulas correspond to a number of H₂O molecules in the hydrate. In some embodiments, compounds for preparing the NiO precursor inks may include nickel nitrate hexahydrate (Ni(NO₃)₂.6H₂O), nickel acetate tetrahydrate (Ni(CH₃CO₂)₂.4H₂O), copper nitrate trihydrate (Cu(NO₃)₂.3H₂O), and copper acetate monohydrate (Cu(CH₃CO₂)₂.H₂O).

Examples of solvents for preparing the NiO precursor ink may include, but are not limited to, one or more of glycerol; ethylene glycol; propylene glycol; methanol; ethanol; and any other compounds comprising at least one hydroxyl groups, such as alcohols and diols; ammonia; acetone; acetylacetone, and any compounds comprising at least one carbonyl group; ethylamine, and any other aryl and alkylamines; ethanolamine, and any amines comprising at least one hydroxyl group; water; di- and polyamines, and any other solvent suitable to dissolve the compounds for preparing the NiO precursor ink. In certain embodiments, a solvent for preparing the NiO precursor inks may include ethylene glycol, ethanolamine and water.

In one particular embodiment, the solvent may include ethylene glycol, ethanolamine and water in a ratio of 12:1.46:1 by volume. In a particular embodiment, the NiO precursor ink consists of Ni(NO₃)₂ and Ni(CH₃CO₂)₂ dissolved in a solvent mixture consisting of a diol, an alcohol amine, and water. In another embodiment, the NiO precursor ink consists of Ni(NO₃)₂ and a metal acetate (M(CH₃CO₂)_{y}) dissolved in a solvent mixture consisting of a diol, an alcohol amine, and water. In another embodiment, the NiO precursor ink consists of Ni(NO₃)₂, Ni(CH₃CO₂)₂ and a metal acetate (M(CH₃CO₂)_{y}) dissolved in a solvent mixture consisting of a diol, an alcohol amine, and water. In another embodiment, the NiO precursor ink consists of Ni(NO₃)₂, Ni(CH₃CO₂)₂ and a metal nitrate (M(NO₃)_{y}) dissolved in a solvent mixture consisting of a diol, an alcohol amine, and water. In another embodiment, the NiO precursor ink consists of Ni(CH₃CO₂)₂, and a metal nitrate (M(NO₃)_{y}) dissolved in a solvent mixture consisting of a diol, an alcohol amine, and water.

An example preparation of the NiO precursor ink may comprise 0.7-0.8 M nickel nitrate hexahydrate and 50-110 mM nickel acetate tetrahydrate in a solvent which comprises ethylene glycol, ethanolamine and water in a volume ratio of 5-20 to 1-5 to 1-5, respectively. In a particular embodiment, the preparation of the NiO precursor ink may comprise 0.72 M nickel nitrate hexahydrate and 103 mM nickel acetate tetrahydrate in a solvent which comprises ethylene glycol, ethanolamine and water in a volume ratio of 12:1.46:1. In some embodiments, the NiO precursor ink may additionally include 0-20 mol % copper and 0-50 mol % acetate.

Another example preparation of the NiO precursor ink may comprise 0.7-0.8 M nickel nitrate and 50-110 mM metal acetate in a solvent which comprises ethylene glycol, ethanolamine and water in a volume ratio of 5-20 to 1-5 to 1-5, respectively. In a particular embodiment, the preparation of the NiO precursor ink may comprise 0.72 M nickel nitrate hexahydrate and 103 mM metal acetate in a solvent which comprises ethylene glycol, ethanolamine and water in a volume ratio of 12:1.46:1. In some embodiments, the NiO precursor ink may additionally include 0-20 mol % copper and 0-50 mol % acetate.

Another example preparation of the NiO precursor ink may comprise 0.7-0.8 M nickel nitrate hexahydrate, 50-110 mM nickel acetate tetrahydrate, and 20-41.3 mM metal nitrate in a solvent which comprises ethylene glycol, ethanolamine and water in a volume ratio of 5-20 to 1-5 to 1-5, respectively. In a particular embodiment, the metal nitrate may be copper nitrate trihydrate. In a particular embodiment, the preparation of the NiO precursor ink may comprise 0.72 M nickel nitrate hexahydrate, 103 mM nickel acetate tetrahydrate, and 30 mM metal nitrate in a solvent which comprises ethylene glycol, ethanolamine and water in a volume ratio of 12:1.46:1.

Another example preparation of the NiO precursor ink may comprise 0.7-0.8 M nickel nitrate hexahydrate, 50-110 mM nickel acetate tetrahydrate, and 20-41.3 mM metal acetate in a solvent which comprises ethylene glycol, ethanolamine and water in a volume ratio of 5-20 to 1-5 to 1-5, respectively. In some embodiments, the metal nitrate may be copper acetate. In a particular embodiment, the preparation of the NiO precursor ink may comprise 0.72 M nickel nitrate hexahydrate, 103 mM nickel acetate tetrahydrate, and 30 mM metal acetate in a solvent which comprises ethylene glycol, ethanolamine and water in a volume ratio of 12:1.46:1.

Another example preparation of the NiO precursor ink may comprise 0.7-0.8 M metal nitrate and 50-110 mM nickel acetate tetrahydrate in a solvent which comprises ethylene glycol, ethanolamine and water in a volume ratio of 5-20 to 1-5 to 1-5, respectively. In a particular embodiment, the preparation of the NiO precursor ink may comprise 0.72 M metal nitrate and 103 mM nickel acetate tetrahydrate in a solvent which comprises ethylene glycol, ethanolamine and water in a volume ratio of 12:1.46:1.

An example method for preparing the NiO precursor solution may include, but is not limited to, the following steps. First, a solvent is prepared comprising diols and amines which comprise at least one hydroxyl group (an “alcohol-amine”). For example, the solvent may be prepared by mixing ethanolamine into ethylene glycol. Next, Ni(NO₃)₂.aH₂O is added to the solvent, where a may be 0, 4, 6 or 9. In particular embodiments, the nickel nitrate may be nickel nitrate hexahydrate (a=6). Next, Ni(CH₃CO₂)₂.bH₂O is added to the mixture, where b may be 0, 2, or 4. The nickel acetate may be nickel acetate tetrahydrate, in particular embodiments. Next, water is added to the mixture. Next, the mixture is heated. Finally, the mixture is cooled to form the NiO precursor ink. In certain embodiments, when each component is added to the mixture, the mixture may be mixed by vibrating, agitating, stirring, homogenizing, combining turbulent flows, vortex mixing, or any other known method of mixing. In certain embodiments, the NiO layer may be prepared in either an inert atmosphere or an atmosphere having a high humidity (e.g. greater than 4 grams H₂O per liter of the atmosphere). In some embodiments, water may be added before the cooling step, so that the final concentration of nickel nitrate hexahydrate is 0.7-0.8 M and the final concentration of nickel acetate tetrahydrate is 50-110 mM.

In some embodiments, an NiO thin film is deposited on an electrode material, e.g., FTO substrate or ITO substrate. As an example, an NiO thin film may be deposited on an electrode substrate. In certain embodiments, the substrate may have a size of 50×50×1.1 mm or 50×50×2.2 mm. In some embodiments, the electrode substrate is cleaned via oxygen plasma prior to NiO deposition. The NiO thin film may be deposited through a variety of means, including but not limited to, drop casting, spin casting, slot-die coating, blade coating, screen printing, or ink-jet printing. In some embodiments, the NiO thin film is deposited on the electrode substrate using slot die coating. Slot-die coating of the lead halide precursor may be performed in a variety of atmospheres at ambient pressure (e.g. about one atmosphere, depending on elevation and atmospheric conditions) or at pressures less than atmospheric or ambient (e.g., 1 mTorr to 500 mTorr). As an example, the NiO precursor solution is deposited on the electrode substrate using slot die coating at a shuttle velocity of from about 0.1 to about 50 mm/s, from about 1 to about 25 mm/s or from about 1 to about 10 mm/s. In certain embodiments, the NiO precursor solution is deposited on the electrode substrate using slot die coating at a shuttle velocity of about 4 mm/s. In one example, the dispensing rate of the NiO precursor solution is from about 0.1 to about 50 μl/s, from about 1 to about 25 μl/s, or from about 1 to about 10 μl/s. In certain embodiments, the dispensing rate of the NiO precursor solution is about 5.5 μl/s.

In some embodiments, the NiO film may be moved onto a heat source (e.g., a hotplate, IR lamp, convection oven, conveyor belt) for annealing. The NiO thin film may be thermally annealed for a time period up to about 24 hours at a temperature of about 20° C. to about 400° C. In certain embodiments, the NiO thin film may be thermally annealed at 310° C. for 1.5-2 hours. Annealing may be performed in a variety of atmospheres at ambient pressure (e.g. about one atmosphere, depending on elevation and atmospheric conditions) or at pressures less than atmospheric or ambient (e.g., 1 mTorr to 500 mTorr). An annealing atmosphere may comprise ambient air, a controlled humidity environment (e.g., 0-100 g H₂O/m³ of gas), pure argon, pure nitrogen, pure oxygen, pure hydrogen, pure helium, pure neon, pure krypton, pure CO₂ or any combination of the preceding gases. As used herein, a “controlled humidity environment” may include an environment in which the absolute humidity or the % relative humidity is held at a fixed value, or in which the absolute humidity or the % relative humidity varies according to predetermined set points or a predetermined function. In particular embodiments, annealing may occur in a controlled humidity environment having a % relative humidity greater than or equal to 0% and less than or equal to 50%. In other embodiments, annealing may occur in a controlled humidity environment containing greater than or equal to 0 g H₂O/m³ gas and less than or equal to 20 g H₂O/m³ gas.

Next, in some embodiments, the electrode substrate with the NiO thin film may be placed in a hotplate to cool down (e.g., for at least 5 minutes or at least 10 minutes) prior to the deposition of the lead halide precursor ink.

Although discussed above with respect to substrates and NiO layers having dimensions of 50×50 mm, the NiO deposition techniques described herein may be applicable to substrates of various sizes including, 50×150 mm, or 150×150 mm. Such techniques may also be scaled up to any suitable size, including sizes suitable for commercial production. For example, in certain embodiments, suitable dimension for substrates and NiO layers formed using one or more methods discussed herein may have a first dimension of from about 1 m to about 2.4 m and a second dimension of from about 0.6 m to about 1.5 m. A person skilled in the art, with the benefit of this disclosure, would appreciate the sizes of substrates and NiO layers (and other types of layers) that could be prepared using the techniques of the present disclosure for a given material and application.

The lead halide precursor ink or the thin film precursor ink may be deposited as described in paragraphs [0070] and [0084].

In one or more embodiments, mechanical or laser scribing may be performed on one or more layers of the PV devices disclosed herein to ablate at least a portion of one or more layers, including, but not limited to electrodes, substrates, IFLs, NiO layers, perovskite material layers, charge transport layers, mesoporous layers, non-conductive layers and/or other layers such as insulating layers. In certain embodiments, the number of scribes performed during formation of a PV device may range from one to five, one to four, one to three, or one to two. In certain embodiments, a first scribe (e.g., P1) may involve scribing the NiO layer during formation of the PV device as described herein. In certain embodiments, the first scribe may, for example, separate the NiO film into two or more strips. In another embodiment, for example, the first scribe may be performed after a perovskite layer is formed and IFLs and an insulating layer (e.g, photoresist layer) is deposited. In some embodiments, a second scribe (e.g., P2) may be performed after deposition of one or more IFLs. In certain embodiments, the second scribe may open a path to create electrical connection between electrodes of one or more sub-cells of a PV device. In some embodiments, a third scribe (e.g., P3) may be performed on an electrode layer. For example, in certain embodiments, the third scribe may isolate two sub-cells from one another. In certain embodiments, for example, a fourth scribe (e.g., P4) may be performed to separate the long cells of a PV device into smaller ones. In certain embodiments, for example, the fourth scribe may be performed perpendicular to one or more other scribes. A person of skill in the art, with the benefit of this disclosure, would understand the number of scribes appropriate for a given device and application, and when and how to apply such scribes.

In certain embodiments, the scribes may include a number of passes ranging from about 1 to about 100, from about 1 to about 50, or from about 5 to about 30. In some embodiments, one or more scribes may include a pitch of from about 1 μm to about 1 mm, from about 0.001 mm to about 0.1 mm, or from about 0.001 mm to about 0.05 mm. In one or more embodiments including laser scribing, the scribing may be performed at about 1 to about 100% power, from about 25% to about 100%, or from about 40% to about 100% power. In one example, a first scribe may be performed at 100% power with 1 pass, a second scribe may be performed at 46.6% power with 28 passes and a 0.008 mm pitch, a third scribe may be performed at 45.5% power with 10 passes and an 0.008 mm pitch, and a fourth scribe may be performed at 100% power with 10 passes and an 0.01 mm pitch. In some embodiments, the scribes of the fourth scribe may include from about 0.1 mm to about 100 mm between scribes, from about 1 to about 50 mm between scribes, and from about 5 to about 30 mm between scribes. Laser scribing may include lasers having a wavelength between about 500 nm and about 1100 nm. In certain embodiments, laser scribing may be performed using a laser having a wavelength of 532 nm or 1068 nm, or any combination thereof.

In some embodiments, the lead halide precursor ink may be deposited through blade coating. The substrate may have a temperature about equal to ambient temperature or have a controlled temperature between 0° C. and 500° C. As an example, the lead halide precursor solution is deposited on the substrate using blade coating with the blade coater set to move at a rate of from about 0.1 mm/s to about 50 mm/s, from about 1 to about 30 mm/s, or from about 5 to about 20 mm/s. In certain embodiments, the lead halide solution is deposited using blade coating with the blade coater set to move at a rate of about 4 mm/s.

Blade coating of the lead halide precursor may be performed in a variety of atmospheres at ambient pressure (e.g. about one atmosphere, depending on elevation and atmospheric conditions) or at pressures less than atmospheric or ambient (e.g., 1 mTorr to 500 mTorr). The blade coating atmosphere may comprise ambient air, a controlled humidity environment (e.g., 0-100 g H₂O/m³ of gas), pure argon, pure nitrogen, pure oxygen, pure hydrogen, pure helium, pure neon, pure krypton, pure CO₂ or any combination of the preceding gases. In particular embodiments, blade coating may occur in a controlled humidity environment having a % relative humidity greater than or equal to 0% and less than or equal to 50%. In other embodiments, blade coating may occur in a controlled humidity environment containing greater than or equal to 0 g H₂O/m³ gas and less than or equal to 20 g H₂O/m³ gas. The lead halide precursor ink may then be allowed to dry in a substantially water-free atmosphere, i.e., less than 30% relative humidity, to form a thin film. In one embodiment, the lead halide precursor ink (e.g., PbI₂) solution) is filtered before blade coating. As an example, the lead iodide precursor ink may be filtered through a PTFE syringe filter.

The lead halide precursor may be a liquid, a gas, solid, or combination of these states of matter such as a solution, suspension, colloid, foam, gel, or aerosol. In some embodiments, the lead halide precursor may be a solution containing one or more solvents. For example, the lead halide precursor may contain one or more of N-cyclohexyl-2-pyrrolidone, alkyl-2-pyrrolidone, dimethylformamide, dialkylformamide, dimethylsulfoxide (DMSO), acetonitrile, methanol, ethanol, propanol, butanol, tetrahydrofuran, formamide, tert-butylpyridine, pyridine, alkylpyridine, pyrrolidine, chlorobenzene, dichlorobenzene, dichloromethane, chloroform, and combinations thereof. The lead halide precursor may comprise a single lead salt (e.g., lead (II) iodide, lead (II) thiocyanate) or any combination of those disclosed herein (e.g., PbI₂+PbCl₂; PbI₂+Pb(SCN)₂). The lead halide precursor may also contain one or more additives such as an amino acid (e.g., 5-aminovaleric acid hydroiodide), 1,8-diiodooctane, 1,8-dithiooctane, formamidinium halide, acetic acid, trifluoroacetic acid, a methylammonium halide, or water. The lead halide precursor ink may be allowed to dry in a substantially water-free atmosphere, i.e., less than 30% relative humidity, to form a thin film.

After blade coating, the thin film may then be thermally annealed for a time period of up to about 24 hours at a temperature of about 20° C. to about 300° C. In one embodiment, the thin film may be thermally annealed for about ten minutes at a temperature of about 50° C. Annealing may be performed in a variety of atmospheres at ambient pressure (e.g. about one atmosphere, depending on elevation and atmospheric conditions) or at pressures less than atmospheric or ambient (e.g., 1 mTorr to 500 mTorr). An annealing atmosphere may comprise ambient air, a controlled humidity environment (e.g., 0-100 g H₂O/m³ of gas), pure argon, pure nitrogen, pure oxygen, pure hydrogen, pure helium, pure neon, pure krypton, pure CO₂ or any combination of the preceding gases. A controlled humidity environment may include an environment in which the absolute humidity or the % relative humidity is held at a fixed value, or in which the absolute humidity or the % relative humidity varies according to predetermined set points or a predetermined function. In particular embodiments, annealing may occur in a controlled humidity environment having a % relative humidity greater than or equal to 0% and less than or equal to 50%. In other embodiments, annealing may occur in a controlled humidity environment containing greater than or equal to 0 g H₂O/m³ gas and less than or equal to 20 g H₂O/m³ gas.

The perovskite material may then be completed by a conversion process in which the precursor film is submerged or rinsed with a solution comprising a solvent or mixture of solvents (e.g., DMF, isopropanol, methanol, ethanol, butanol, chloroform chlorobenzene, dimethylsulfoxide, water) and salt (e.g., methylammonium iodide, formamidinium iodide, guanidinium iodide, 1,2,2-triaminovinylammonium iodide, 5-aminovaleric acid hydroiodide) in a concentration between 0.001M and 10M. The conversion process may be performed in a variety of atmospheres at ambient pressure (e.g. about one atmosphere, depending on elevation and atmospheric conditions) or at pressures less than atmospheric or ambient (e.g., 1 mTorr to 500 mTorr). The conversion atmosphere may include ambient air, a controlled humidity environment (e.g., 0-100 g H₂O/m³ of gas), pure argon, pure nitrogen, pure oxygen, pure hydrogen, pure helium, pure neon, pure krypton, pure CO₂ or any combination of the preceding gases. In particular embodiments, the conversion process may occur in a controlled humidity environment having a % relative humidity greater than or equal to 0% and less than or equal to 50%. In other embodiments, the conversion process may occur in a controlled humidity environment containing greater than or equal to 0 g H₂O/m³ gas and less than or equal to 20 g H₂O/m³ gas.

In certain embodiments, the thin films may also be thermally post-annealed in various embodiments and environments described above with respect to the other annealing step.

Once the lead halide thin-film is deposited, the substrates including the lead halide film may be coated with one or more coats of a BzAI solution, followed by one or more coats of FAI solution. In other embodiments, the lead halide films may be coated with one, two or three coats of BzAI solution and one, two or three coats of FAI solution, and any combination thereof. In one example, the BzAI solution and/or FAI solutions are coated on the lead halide film using slot die coating at a shuttle velocity of from about 0.1 to about 50 mm/s, from about 1 to about 25 mm/s or from about 1 to about 10 mm/s. In certain embodiments, the BzAI solution and/or FAI solutions are deposited on the electrode substrate using slot die coating at a shuttle velocity of about 12 mm/s. In one example, the slot die coating dispensing rate of the BzAI solution and/or FAI solutions are from about 0.1 to about 50 μl/s, from about 1 to about 25 μl/s, or from about 1 to about 10 μl/s. In certain embodiments, the slot die coating dispensing rate of the BzAI solution and/or FAI solutions are about 5.5 μl/s. In certain embodiments, the BzAI and/or FAI solutions are deposited using blade coating with the blade coater set to move at a rate of from about 0.1 mm/s to about 50 mm/s, from about 1 to about 30 mm/s, or from about 5 to about 20 mm/s. In certain embodiments, the BzAI and/or FAI solutions are deposited using blade coating with the blade coater set to move at a rate of about 4 mm/s. The coating atmosphere for the BzAI and/or FAI solution may comprise ambient air, a controlled humidity environment (e.g., 0-100 g H₂O/m³ of gas), pure argon, pure nitrogen, pure oxygen, pure hydrogen, pure helium, pure neon, pure krypton, pure CO₂ or any combination of the preceding gases. In particular embodiments, the slot-die or blade coating may occur in a controlled humidity environment having a % relative humidity greater than or equal to 0% and less than or equal to 50%. In other embodiments, the slot-die or blade coating may occur in a controlled humidity environment containing greater than or equal to 0 g H₂O/m³ gas and less than or equal to 20 g H₂O/m³ gas. The BzAI and/or FAI solution may then be allowed to dry in a substantially water-free atmosphere, i.e., less than 30% relative humidity, to form a thin film. The BzAI and/or FAI solution may then be allowed to dry in a substantially water-free atmosphere, i.e., less than 30% relative humidity, to form a thin film.

Next, the substrates may be moved onto a heat source (e.g., a hotplate, IR lamp, convection oven, conveyor belt) for annealing. After coating with BzAI and/or FAI solution, the thin film may then be thermally annealed for a time period of up to about 24 hours at a temperature of about 20° C. to about 300° C. In one embodiment, the thin film may be thermally annealed for about ten minutes at a temperature of about 50° C. Annealing may be performed in a variety of atmospheres at ambient pressure (e.g. about one atmosphere, depending on elevation and atmospheric conditions) or at pressures less than atmospheric or ambient (e.g., 1 mTorr to 500 mTorr). An annealing atmosphere may comprise ambient air, a controlled humidity environment (e.g., 0-100 g H₂O/m³ of gas), pure argon, pure nitrogen, pure oxygen, pure hydrogen, pure helium, pure neon, pure krypton, pure CO₂ or any combination of the preceding gases. A controlled humidity environment may include an environment in which the absolute humidity or the % relative humidity is held at a fixed value, or in which the absolute humidity or the % relative humidity varies according to predetermined set points or a predetermined function. In particular embodiments, annealing may occur in a controlled humidity environment having a % relative humidity greater than or equal to 0% and less than or equal to 50%. In other embodiments, annealing may occur in a controlled humidity environment containing greater than or equal to 0 g H₂O/m³ gas and less than or equal to 20 g H₂O/m³ gas.

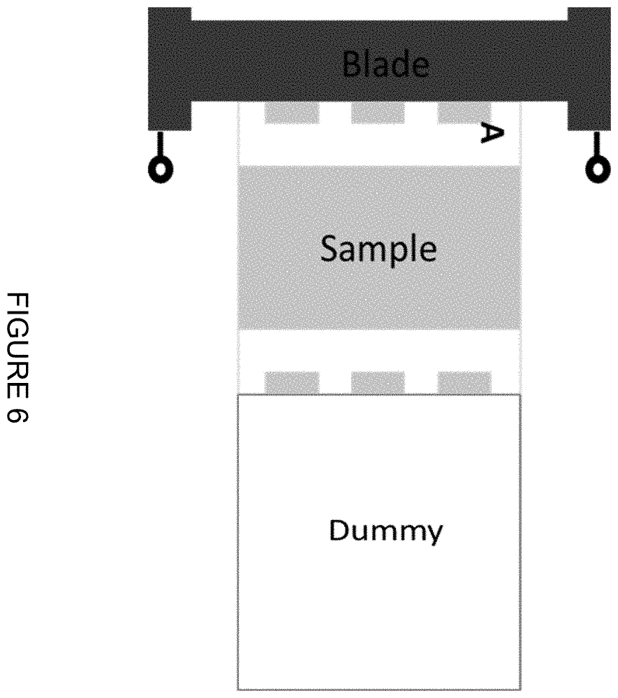

FIG. 6 is a stylized illustration of a blade coating setup according to certain embodiments. First, the lead halide precursor ink is deposited onto one or more substrates comprising an NiO film and subsequently annealed to form a lead halide film. In the example shown in FIG. 6, the sample substrate comprising the NiO film is placed between an ITO dummy substrate and the blade. In certain embodiments, both the sample substrate and the dummy substrate may have dimensions of 50×50 mm. In other embodiments, the substrates may have different sizes, and a person skilled in the art with the benefit of this disclosure would understand the sizes suitable for a given deposition process. The two substrates are pushed together, and vacuum is applied to ensure the substrates are touching without gaps. Next, the lead halide precursor ink (e.g., PbI₂ solution) may be connected to the blade and the blade coater is set to a forward direction at a constant rate (e.g., 14 mm/s). After the blade reaches a certain position on the ITO dummy substrate (e.g., a minimum of ¾ of the dummy substrate), the blade coater is set to reverse back to the original position and vacuum is turned off at the same time. Next, the sample substrates may be removed from the blade coater and annealed via a heat source (e.g., a hotplate, IR lamp, convection oven, conveyor belt, etc.). The thin film may be thermally annealed for a time period up to about 24 hours at a temperature of about 20° C. to about 300° C. In one embodiments, the thin film may be thermally annealed for about ten minutes at a temperature of about 50° C.

Next, to form the perovskite material layer, the lead halide film on the one or more substrates is placed back on the blade coater in the configuration shown in FIG. 6 and is first coated with one coat of a BzAI solution, followed by three coats of a FAI solution. Following deposition of each of the coats of BzAI solution and FAI solution, the coat is allowed to dry prior to deposition of the following coating. The BzAI and FAI solutions may be prepared in the manner discussed above by dissolving FAI and BzAI in IPA. In one example, the BzAI solution is coated on the lead iodide film at a constant rate (e.g., 12 mm/s). After the blade reaches a certain position on the ITO dummy substrate (e.g., a minimum of ¾ of the dummy substrate), the blade coater is set to reverse back to the original position. Next, the FAI solution is connected to the blade coater and the FAI solution is coated on the lead iodide film at a constant rate (e.g., 12 mm/s). After the blade reaches a certain position on the ITO dummy substrate (e.g., a minimum of ¾ of the dummy substrate), the blade coater is set to reverse back to the original position. The FAI coating process may be repeated one, two, three, or more times. In one example, three coats of FAI are layered onto the BzAI solution. Next, the sample substrates may be removed from the blade coater and annealed via a heat source (e.g., a hotplate, IR lamp, convection oven, conveyor belt, etc.). The thin film may be thermally annealed for a time period up to about 24 hours at a temperature of about 20° C. to about 300° C. In one embodiments, the thin film may be thermally annealed for about five minutes at a temperature of about 157° C.

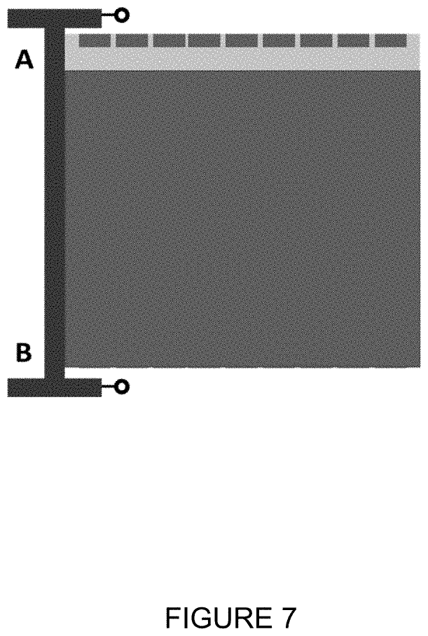

FIG. 7 is a stylized illustration of another blade coating setup for forming a perovskite material layer. First, the lead halide precursor ink (e.g., PbI₂ solution) is deposited onto one or more substrates comprising an NiO film and subsequently annealed to form a lead halide film. In the example shown in FIG. 7, a dummy substrate having a size of 150×50 mm is placed on the blade coater and then the substrate comprising the NiO film is placed between the dummy substrate and the blade. The two substrates are pushed together, and a vacuum is applied on to ensure the substrates are touching without gaps. Next, the lead halide precursor ink (e.g., PbI₂ solution) is connected to the blade and the blade coater is set to move forward at a constant rate (e.g., 5 mm/s). After the blade reaches a certain position on the ITO dummy substrate (e.g., a minimum of ¾ of the dummy substrate), the blade coater is set to reverse back to the original position and vacuum is turned off at the same time. Next, the sample substrates may be removed from the blade coater and annealed via a heat source (e.g., a hotplate, IR lamp, convection oven, conveyor belt, etc.). The thin film may be thermally annealed for a time period up to about 24 hours at a temperature of about 20° C. to about 300° C. In one embodiments, the thin film may be thermally annealed for about ten minutes at a temperature of about 50° C.

Next, to form the perovskite material layer, the lead halide film on the one or more substrates is placed back on the blade coater in the configuration shown in FIG. 7 and is first coated with one coat of the BzAI solution, followed with three coats of FAI solution. Following deposition of each of the coats of BzAI solution and FAI solution, the coat is allowed to dry prior to deposition of the following coating. The BzAI and FAI solutions may be prepared in the manner discussed above. In one example, the BzAI solution is coated on the lead iodide film at a constant rate (e.g., 7 mm/s). Next, the FAI solution is connected to the blade coater and the FAI solution is coated on the lead iodide film at a constant rate (e.g., 7 mm/s). The FAI coating process may be repeated one, two, three, or more times. In one example, three coats of FAI are layered onto the BzAI solution. Next, the sample substrates may be removed from the blade coater and annealed via a heat source (e.g., a hotplate, IR lamp, convection oven, conveyor belt, etc.). The thin film may be thermally annealed for a time period up to about 24 hours at a temperature of about 20° C. to about 300° C. In one embodiments, the thin film may be thermally annealed for about five minutes at a temperature of about 157° C.

In some embodiments, the lead halide precursor ink may be deposited through slot-die coating. Slot-die coating of the lead halide precursor may be performed in a variety of atmospheres at ambient pressure (e.g. about one atmosphere, depending on elevation and atmospheric conditions) or at pressures less than atmospheric or ambient (e.g., 1 mTorr to 500 mTorr). As an example, the lead halide precursor solution is deposited on the substrate using slot die coating at a shuttle velocity of from about 0.1 to about 50 mm/s, from about 1 to about 25 mm/s or from about 1 to about 10 mm/s. In certain embodiments, the lead halide precursor solution is deposited on the electrode substrate using slot die coating at a shuttle velocity of about 12 mm/s. In one example, the dispensing rate of the lead halide precursor solution is from about 0.1 to about 50 μl/s, from about 1 to about 25 μl/s, or from about 1 to about 10 μl/s. In certain embodiments, the dispensing rate of the lead halide precursor solution is about 5.5 μl/s.

The slot-die coating atmosphere may comprise ambient air, a controlled humidity environment (e.g., 0-100 g H₂O/m³ of gas), pure argon, pure nitrogen, pure oxygen, pure hydrogen, pure helium, pure neon, pure krypton, pure CO₂ or any combination of the preceding gases. In particular embodiments, the slot-die coating may occur in a controlled humidity environment having a % relative humidity greater than or equal to 0% and less than or equal to 50%. In other embodiments, the slot-die coating may occur in a controlled humidity environment containing greater than or equal to 0 g H₂O/m³ gas and less than or equal to 20 g H₂O/m³ gas. The lead halide precursor ink may then be allowed to dry in a substantially water-free atmosphere, i.e., less than 30% relative humidity, to form a thin film. In one embodiment, the lead halide precursor ink (e.g., PbI₂ solution) is filtered before slot-die coating. As an example, the lead iodide precursor ink may be filtered through a PTFE syringe filter. The lead halide precursor ink may then be allowed to dry in a substantially water-free atmosphere, i.e., less than 30% relative humidity, to form a thin film. In one embodiment, the lead halide precursor ink (e.g., PbI₂ solution) is filtered prior to slot-die coating. As an example, the lead iodide precursor ink may be filtered through a PTFE syringe filter.

The lead halide precursor may be a liquid, a gas, solid, or combination of these states of matter such as a solution, suspension, colloid, foam, gel, or aerosol. In some embodiments, the lead halide precursor may be a solution containing one or more solvents. For example, the lead halide precursor may contain one or more of N-cyclohexyl-2-pyrrolidone, alkyl-2-pyrrolidone, dimethylformamide, dialkylformamide, dimethylsulfoxide (DMSO), acetonitrile, methanol, ethanol, propanol, butanol, tetrahydrofuran, formamide, tert-butylpyridine, pyridine, alkylpyridine, pyrrolidine, chlorobenzene, dichlorobenzene, dichloromethane, chloroform, and combinations thereof. The lead halide precursor may comprise a single lead salt (e.g., lead (II) iodide, lead (II) thiocyanate) or any combination of those disclosed herein (e.g., PbI₂+PbCl₂; PbI₂+Pb(SCN)₂). The lead halide precursor may also contain one or more additives such as an amino acid (e.g., 5-aminovaleric acid hydroiodide), 1,8-diiodooctane, 1,8-dithiooctane, formamidinium halide, acetic acid, trifluoroacetic acid, a methylammonium halide, or water. The lead halide precursor ink may be allowed to dry in a substantially water-free atmosphere, i.e., less than 30% relative humidity, to form a thin film.

After slot-die coating, the thin film may then be thermally annealed for a time period of up to about 24 hours at a temperature of about 20° C. to about 300° C. In one embodiment, the thin film may be thermally annealed for about ten minutes at a temperature of about 50° C. Annealing may be performed in a variety of atmospheres at ambient pressure (e.g. about one atmosphere, depending on elevation and atmospheric conditions) or at pressures less than atmospheric or ambient (e.g., 1 mTorr to 500 mTorr). An annealing atmosphere may comprise ambient air, a controlled humidity environment (e.g., 0-100 g H₂O/m³ of gas), pure argon, pure nitrogen, pure oxygen, pure hydrogen, pure helium, pure neon, pure krypton, pure CO₂ or any combination of the preceding gases. A controlled humidity environment may include an environment in which the absolute humidity or the % relative humidity is held at a fixed value, or in which the absolute humidity or the % relative humidity varies according to predetermined set points or a predetermined function. In particular embodiments, annealing may occur in a controlled humidity environment having a % relative humidity greater than or equal to 0% and less than or equal to 50%. In other embodiments, annealing may occur in a controlled humidity environment containing greater than or equal to 0 g H₂O/m³ gas and less than or equal to 20 g H₂O/m³ gas.

The perovskite material may then be completed by a conversion process in which the precursor film is submerged or rinsed with a solution comprising a solvent or mixture of solvents (e.g., DMF, isopropanol, methanol, ethanol, butanol, chloroform chlorobenzene, dimethylsulfoxide, water) and salt (e.g., methylammonium iodide, formamidinium iodide, guanidinium iodide, 1,2,2-triaminovinylammonium iodide, 5-aminovaleric acid hydroiodide) in a concentration between 0.001M and 10M. The conversion process may be performed in a variety of atmospheres at ambient pressure (e.g. about one atmosphere, depending on elevation and atmospheric conditions) or at pressures less than atmospheric or ambient (e.g., 1 mTorr to 500 mTorr). The conversion atmosphere may include ambient air, a controlled humidity environment (e.g., 0-100 g H₂O/m³ of gas), pure argon, pure nitrogen, pure oxygen, pure hydrogen, pure helium, pure neon, pure krypton, pure CO₂ or any combination of the preceding gases. In particular embodiments, the conversion process may occur in a controlled humidity environment having a % relative humidity greater than or equal to 0% and less than or equal to 50%. In other embodiments, the conversion process may occur in a controlled humidity environment containing greater than or equal to 0 g H₂O/m³ gas and less than or equal to 20 g H₂O/m³ gas. In certain embodiments, the thin films may also be thermally post-annealed in various embodiments and environments described above with respect to the other annealing step.

Once the lead halide thin-film is deposited, the substrates including the lead halide film may be coated with one or more coats of a BzAI solution, followed by one or more coats of FAI solution. In other embodiments, the lead halide films may be coated with one, two or three coats of BzAI solution and one, two or three coats of FAI solution, and any combination thereof. In one example, the BzAI solution and/or FAI solutions are coated on the lead halide film using slot die coating at a shuttle velocity of from about 0.1 to about 50 mm/s, from about 1 to about 25 mm/s or from about 1 to about 10 mm/s. In certain embodiments, the BzAI solution and/or FAI solutions are deposited on the electrode substrate using slot die coating at a shuttle velocity of about 12 mm/s. In one example, the slot die coating dispensing rate of the BzAI solution and/or FAI solutions are from about 0.1 to about 50 μl/s, from about 1 to about 25 μl/s, or from about 1 to about 10 μl/s. In certain embodiments, the slot die coating dispensing rate of the BzAI solution and/or FAI solutions are about 5.5 μl/s. In certain embodiments, the BzAI and/or FAI solutions are deposited using blade coating with the blade coater set to move at a rate of from about 0.1 mm/s to about 50 mm/s, from about 1 to about 30 mm/s, or from about 5 to about 20 mm/s. In certain embodiments, the BzAI and/or FAI solutions are deposited using blade coating with the blade coater set to move at a rate of about 4 mm/s. The coating atmosphere for the BzAI and/or FAI solution may comprise ambient air, a controlled humidity environment (e.g., 0-100 g H₂O/m³ of gas), pure argon, pure nitrogen, pure oxygen, pure hydrogen, pure helium, pure neon, pure krypton, pure CO₂ or any combination of the preceding gases. In particular embodiments, the slot-die or blade coating may occur in a controlled humidity environment having a % relative humidity greater than or equal to 0% and less than or equal to 50%. In other embodiments, the slot-die or blade coating may occur in a controlled humidity environment containing greater than or equal to 0 g H₂O/m³ gas and less than or equal to 20 g H₂O/m³ gas. The BzAI and/or FAI solution may then be allowed to dry in a substantially water-free atmosphere, i.e., less than 30% relative humidity, to form a thin film. The BzAI and/or FAI solution may then be allowed to dry in a substantially water-free atmosphere, i.e., less than 30% relative humidity, to form a thin film.

Next, the substrates may be annealed via a heat source (e.g., a hotplate, IR lamp, convection oven, conveyor belt, etc.). After coating with BzAI and/or FAI solution, the thin film may then be thermally annealed for a time period of up to about 24 hours at a temperature of about 20° C. to about 300° C. In one embodiment, the thin film may be thermally annealed for about ten minutes at a temperature of about 50° C. Annealing may be performed in a variety of atmospheres at ambient pressure (e.g. about one atmosphere, depending on elevation and atmospheric conditions) or at pressures less than atmospheric or ambient (e.g., 1 mTorr to 500 mTorr). An annealing atmosphere may comprise ambient air, a controlled humidity environment (e.g., 0-100 g H₂O/m³ of gas), pure argon, pure nitrogen, pure oxygen, pure hydrogen, pure helium, pure neon, pure krypton, pure CO₂ or any combination of the preceding gases. A controlled humidity environment may include an environment in which the absolute humidity or the % relative humidity is held at a fixed value, or in which the absolute humidity or the % relative humidity varies according to predetermined set points or a predetermined function. In particular embodiments, annealing may occur in a controlled humidity environment having a % relative humidity greater than or equal to 0% and less than or equal to 50%. In other embodiments, annealing may occur in a controlled humidity environment containing greater than or equal to 0 g H₂O/m³ gas and less than or equal to 20 g H₂O/m³ gas.

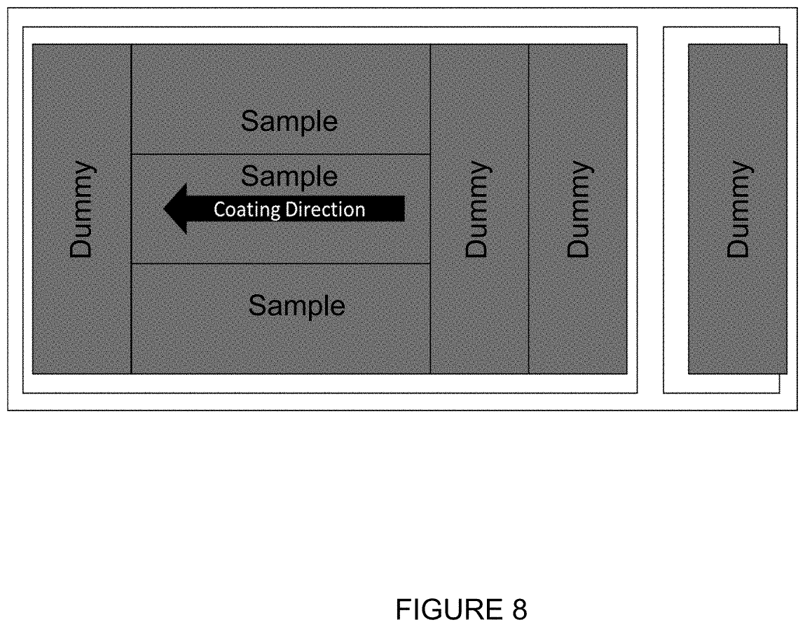

FIG. 8 is a stylized illustration of a slot die coating setup for manufacturing a perovskite material layer. In the example shown in FIG. 8, three horizontal sample substrates each having a size of 50×150 mm are placed in the slot die coater along with four 150 mm dummy substrates, as arranged in FIG. 8. In other embodiments, the substrates may have different sizes, and a person skilled in the art with the benefit of this disclosure would understand the sizes suitable for a given slot die coating process. Next, the lead halide precursor ink (e.g., PbI₂ solution) is deposited onto the substrates at a constant shuttle velocity (e.g., 12 mm/s). Next, the sample substrates may be removed from the slot die coater and annealed via a heat source (e.g., a hotplate, IR lamp, convection oven, conveyor belt, etc.). The thin film may be thermally annealed for a time period up to about 24 hours at a temperature of about 20° C. to about 300° C. In one embodiments, the thin film may be thermally annealed for about 10 minutes at a temperature of about 50° C.

Next, to form the perovskite material layer, the sample substrates comprising the lead halide film are placed back on the slot die coater with dummy substrates in the configuration of FIG. 8 and are then coated with one coat of the BzAI solution, followed by three coats of FAI solution. In other embodiments, the lead halide films may be coated with one, two or three coats of BzAI solution and one, two or three coats of FAI solution, and any combination thereof. In one example, the BzAI solution is coated on the lead iodide film at a constant shuttle velocity (e.g., 8 mm/s). Next, the FAI solution is connected to the slot die coater and the FAI solution is coated on the lead iodide film at a constant shuttle velocity (e.g., 8 mm/s). In this example, this process is repeated until three coats of FAI are deposited. Next, the sample substrates may be removed from the slot die coater and annealed via a heat source (e.g., a hotplate, IR lamp, convection oven, conveyor belt, etc.). The thin film may be thermally annealed for a time period up to about 24 hours at a temperature of about 20° C. to about 300° C. In one embodiments, the thin film may be thermally annealed for about five minutes at a temperature of about 157° C.

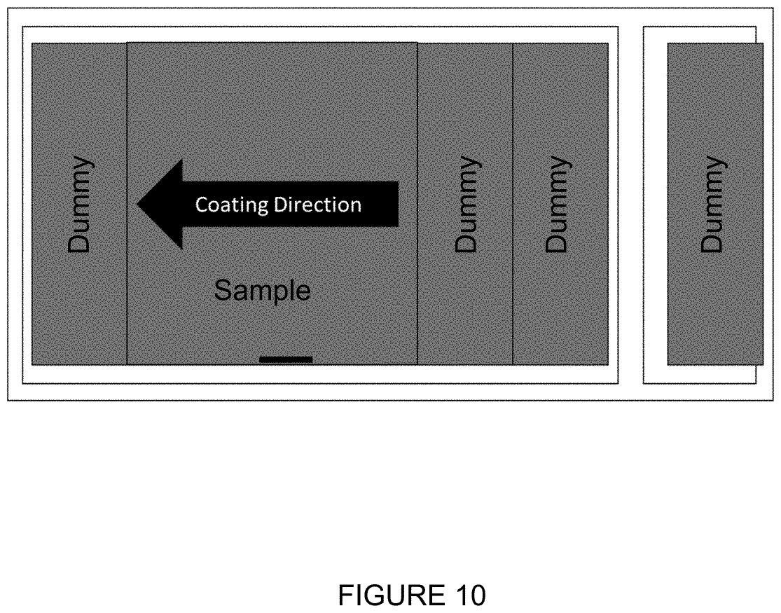

FIG. 10 is a stylized illustration of a slot die coating setup for manufacturing a perovskite material layer. According to this example, a first scribe is performed with a laser scribing device under the NiO layer on a substrate. In this example, the first scribe includes 1 pass at 100% power, but scribing parameters could vary as discussed above (including the use of mechanical scribing). Additionally, the first scribe could be reserved until after the deposition of the C₆₀ and bathocuproine layers, as discussed below. Next, the scribed NiO sample substrates may be annealed via a heat source (e.g., a hotplate, IR lamp, convection oven, conveyor belt, etc.). The NiO film may be thermally annealed for a time period up to about 24 hours at a temperature of about 20° C. to about 300° C. In one embodiment, the NiO film may be thermally annealed for about 30 minutes at a temperature of about 310° C. Next, a previously prepared lead halide solution (prepared in accordance with the discussion above) is filtered in a 15% humidity environment. Next, the scribed NiO substrate having a size of 150×150 mm is placed in the slot die coater along with four 50×150 mm dummy substrates, as arranged in FIG. 10. In other embodiments, the substrates may have different sizes, and a person skilled in the art with the benefit of this disclosure would understand the sizes suitable for a given slot die coating process. Next, the filtered lead halide precursor ink (e.g., PbI₂ solution) is deposited onto the substrates at a constant shuttle velocity (e.g., 12 mm/s) at 25% humidity. Next, the sample substrates may be removed from the slot die coater and annealed via a heat source (e.g., a hotplate, IR lamp, convection oven, conveyor belt, etc.). The thin film may be thermally annealed for a time period up to about 24 hours at a temperature of about 20° C. to about 300° C. In one embodiment, the lead halide thin film may be thermally annealed for ten minutes at a temperature of about 50° C.

Next, to form the perovskite material layer, the sample substrates comprising the lead halide film are placed back on the slot die coater with dummy substrates in the configuration of FIG. 10 and are then coated with one coat of the BzAI solution, followed by three coats of FAI solution. In other embodiments, the lead halide films may be coated with one, two or three coats of BzAI solution and one, two or three coats of FAI solution, and any combination thereof. In one example, the BzAI solution is coated on the lead iodide film at a constant shuttle velocity (e.g., 8 mm/s). Next, the FAI solution is connected to the slot die coater and the FAI solution is coated on the lead iodide film at a constant shuttle velocity (e.g., 8 mm/s). In this example, this process is repeated until three coats of FAI are deposited. Next, the sample substrates may be removed from the slot die coater and annealed via a heat source (e.g., a hotplate, IR lamp, convection oven, conveyor belt, etc.). The thin film may be thermally annealed for a time period up to about 24 hours at a temperature of about 20° C. to about 300° C. In one embodiment, the thin film may be thermally annealed for about 5 minutes at a temperature of about 157° C. Next, the substrates are coated with a C₆₀ layer followed by a bathocuproine (BCP) layer. The C₆₀ and bathocuproine (BCP) layers could be deposited through a variety of means, including but not limited to, drop casting, spin casting, slot-die coating, blade coating, screen printing, or ink-jet printing. In some embodiments, the Cho layer may be from about 0.1 to 1,000 nm thick, and the bathocuproine (BCP) layer may be from about 0.1 to about 1,000 nm thick. For example, the Cho layer may be 30 nm thick, and the bathocuproine (BCP) layer may be from about 15 nm thick. In certain embodiments, if the first scribe was not performed under the NiO layer, an insulating layer (e.g., photoresist layer) may then be deposited and the first scribe may be performed on the insulating layer.

Next, the second scribe may be performed along with hand-scribing the edges of the substrate and thin-film layers. In certain embodiments, the second scribe may include a number of passes ranging from about 1 to about 100, from about 1 to about 50, or from about 5 to about 30. In some embodiments, the second scribe may include a pitch of from about 1 μm to about 1 mm, from about 0.001 mm to about 0.1 mm, or from about 0.001 mm to about 0.05 mm. In one or more embodiments including laser scribing, the second scribe may be performed at about 1 to about 100% power, from about 25% to about 100%, or from about 40% to about 100% power. In one example, the second scribe may be performed at 46.6% power with 28 passes and a 0.008 mm pitch. The second scribe could be performed by laser or mechanical scribing.

Next, a copper electrode layer and an alumina layer may be deposited. The copper and alumina layers could be deposited through a variety of means, including but not limited to, drop casting, spin casting, slot-die coating, blade coating, screen printing, or ink-jet printing. In some embodiments, the copper and alumina layers may each be from about 0.1 to 1,000 nm thick. For example, the copper layer may be 400 nm thick.

Next, a third scribe may be performed. In certain embodiments, the third scribe may include a number of passes ranging from about 1 to about 100, from about 1 to about 50, or from about 5 to about 30. In some embodiments, the third scribe may include a pitch of from about 1 μm to about 1 mm, from about 0.001 mm to about 0.1 mm, or from about 0.001 mm to about 0.05 mm. In one or more embodiments including laser scribing, the third scribe may be performed at from about 1 to about 100% power, from about 25% to about 100%, or from about 40% to about 100% power. In one example, the third scribe may be performed at 46.6% power with 28 passes and a 0.008 mm pitch. The third scribe could be performed by laser or mechanical scribing.

Next, a fourth scribe may be performed. In certain embodiments, the fourth scribe may include a number of passes ranging from about 1 to about 100, from about 1 to about 50, or from about 5 to about 30. In some embodiments, the fourth scribe may include a pitch of from about 1 μm to about 1 mm, from about 0.001 mm to about 0.1 mm, or from about 0.001 mm to about 0.05 mm. In one or more embodiments including laser scribing, the fourth scribe may be performed at from about 1 to about 100% power, from about 25% to about 100%, or from about 40% to about 100% power. In one example, the fourth scribe may be performed at 100% power with 10 passes and an 0.01 mm pitch. The fourth scribe could be performed by laser or mechanical scribing.

Although discussed above largely with respect to substrates and perovskite material layers having dimensions of 50×50 mm, 50×150 mm, or 150×150 mm, the techniques described herein may be scaled up to any suitable size (e.g., to a size suitable for commercial production). For example, in certain embodiments, suitable dimension for substrates and perovskite material layers formed using one or more methods discussed herein may have a first dimension of from about 1 m to about 2.4 m and a second dimension of from about 0.6 m to about 1.5 m. A person skilled in the art, with the benefit of this disclosure, would appreciate the sizes of substrates and perovskite material layers (and other types of layers) that could be prepared using the techniques of the present disclosure for a given material and application.

Numerous modifications, alterations, and changes to the described embodiments are possible without departing from the scope of the present invention defined in the claims. It is intended that the present invention not be limited to the described embodiments, but that it has the full scope defined by the language of the following claims, and equivalents thereof

What is claimed is:

1. A method comprising:
forming a lead halide precursor thin film, wherein forming the lead halide precursor thin film comprises:
depositing a lead halide precursor ink onto a substrate;
drying the lead halide precursor ink to form a first thin film; and
annealing the first thin film; and
forming a perovskite material layer, wherein forming the perovskite material layer comprises:
depositing a benzylammonium halide precursor ink onto the first thin film;
drying the benzylammonium halide precursor ink;
depositing a formamidinium halide precursor ink onto the benzylammonium halide precursor ink;
drying the formamidinium halide precursor ink to form a second thin film; and
annealing the second thin film.

2. The method of claim 1, wherein the lead halide comprises lead (II) iodide.

3. The method of claim 1, wherein the lead halide precursor ink is deposited onto the substrate through blade coating or slot die coating.

4. The method of claim 1, wherein the first thin film is annealed at 50° C. for 10 minutes.

5. The method of claim 1, wherein the benzylammonium halide comprises benzylammonium iodide.

6. The method of claim 1, wherein the formamidinium halide comprises formamidinium iodide.

7. The method of claim 1, wherein the benzylammonium halide precursor ink and the formamidinium halide precursor ink are deposited onto the substrate through blade coating or slot die coating.

8. The method of claim 1, wherein second thin film is annealed at 157° C. for 5 minutes.

9. The method of claim 1, wherein the lead halide precursor ink is deposited onto a nickel oxide substrate.

10. The method of claim 9, wherein the nickel oxide substrate is formed by a process comprising the steps of:
depositing a nickel oxide precursor ink on an electrode material to form a third thin film; and
annealing the third thin film.

11. A perovskite material prepared by a process comprising the steps of:
forming a lead halide precursor thin film, wherein forming the lead halide precursor thin film comprises:
depositing a lead halide precursor ink onto a substrate;
drying the lead halide precursor ink to form a first thin film; and
annealing the first thin film; and
forming a perovskite material layer, wherein forming the perovskite material layer comprises:
depositing a benzylammonium halide precursor ink onto the first thin film;
drying the benzylammonium halide precursor ink;
depositing a formamidinium halide precursor ink onto the benzylammonium halide precursor ink;
drying the formamidinium halide precursor ink to form a second thin film; and
annealing the second thin film.

12. The perovskite material of claim 11, wherein the lead halide comprises lead (II) iodide.

13. The perovskite material of claim 11, wherein the lead halide precursor ink is deposited onto the substrate through blade coating or slot die coating.

14. The perovskite material of claim 11, wherein the first thin film is annealed at 50° C. for 10 minutes.

15. The perovskite material of claim 11, wherein the benzylammonium halide comprises benzylammonium iodide.

16. The perovskite material of claim 11, wherein the formamidinium halide comprises formamidinium iodide.

17. The perovskite material of claim 11, wherein the benzylammonium halide precursor ink and the formamidinium halide precursor ink are deposited onto the substrate through blade coating or slot die coating.

18. The perovskite material of claim 11, wherein second thin film is annealed at 157° C. for 5 minutes.

19. The perovskite material of claim 11, wherein the lead halide precursor ink is deposited onto a nickel oxide substrate.

20. The perovskite material of claim 19, wherein the nickel oxide substrate is formed by a process comprising the steps of:
depositing a nickel oxide precursor ink on an electrode material to form a third thin film; and
annealing the third thin film.
